(19) United States
(12) Patent Application Publication
(10) Pub. No.: US 2015/0123240 A1
(43) Pub. Date: May 7, 2015

(54) Semiconductor Device and Method of Forming Shallow P-N Junction with Sealed Trench Termination

(71) Applicant: Addison R. Crockett, Tempe, AZ (US)

(72) Inventors: Ronald R. Bowman, Chandler, AZ (US); Addison R. Crockett, Tempe, AZ (US)

(73) Assignee: Addison R. Crockett, Tempe, AZ (US)

(21) Appl. No.: 14/074,533

(22) Filed: Nov. 7, 2013

(51) Int. Cl. H01L 29/06; H01L 21/18; H01L 21/762

(52) U.S. Cl. CPC H01L 29/0688; H01L 29/0649; H01L 21/76224; H01L 21/185
USPC 257/506; 438/437

(57) ABSTRACT

A semiconductor device has a substrate including a semiconductor material of a first conductivity type. A first layer including a semiconductor material of a second conductivity type is formed in the substrate with a boundary between the first layer and the semiconductor material of the first conductivity type as a p-n junction. A vertical trench is formed through the first layer by anisotropic etch and extends at least to the boundary. The vertical trench has a rounded or polygonal shape with a depth less than 40 micrometers. An insulating material is deposited in the vertical trench. An insulating layer is formed over a sidewall of the vertical trench. The shallow vertical trench filled with insulating material increases breakdown voltage and reduces manufacturing time and complexity. The semiconductor device can be a discrete diode, transistor, rectifier, transient voltage suppressor, silicon controlled rectifier, and triode.

### FIELD OF THE INVENTION

The present invention relates in general to semiconductor devices and, more particularly, to a semiconductor device and method of forming a shallow p-n junction with a sealed trench termination to provide improved electrical characteristics.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components to perform more complex analog and digital functions. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The active and passive structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation. The term “semiconductor die” as used herein refers to both the singular and plural form of the words, and accordingly can refer to both a single semiconductor device and multiple semiconductor devices.

Semiconductor devices come in a variety of package types and perform specific functions. Some common types of semiconductor devices are integrated circuits (ICs) and discrete devices, such as transistors, diodes, rectifiers, transit voltage suppressors (TVS), silicon controlled rectifiers (SCR), and thyristors. Discrete semiconductor devices perform specific functions such as signal rectification and power transfer. For example, a thyristor is a solid state discrete semiconductor device with four layers of alternating n-type and p-type semiconductor material, i.e., p-n-p-n or n-p-n-p. The thyristor operates as a switch, conducting when the gate receives a current pulse, and continuing to conduct while forward biased.

Many discrete semiconductor devices, such as diodes, SCRs, and thyristors, are manufactured by a planar process or mesa process. FIG. 1 illustrates a cross-sectional view of a conventional diode 10 containing a p-n junction, e.g., rectifier, small signal, or Zener diode. Diode 10 is made with a planar process. An n− epitaxial (epi) layer 11 formed in n+ substrate 12. Substrate 12 provides structural support for the device. A p region 13 is formed in epi layer 11 coplanar with the surface of the epi layer. The planar process may have a silicon dioxide (SiO2) layer formed over the device. The p-n junction is formed between p region 13 and n− epi layer 11.

FIG. 2 shows a conventional transistor 14 made with a planar process. An n− epi layer 15 formed in n+ substrate 16. Substrate 16 provides structural support for the device. A p region 17 is formed in epi layer 15 coplanar with the surface of the epi layer. An n region 18 is formed in p region 17 coplanar with the surface of the p region. The planar process may have a SiO2 layer formed over the device. The vertical bipolar transistor is formed between n− epi layer 15, p region 17, and n region 18.

FIG. 3 shows a conventional diode 20 containing a p-n junction made with a mesa process. An n− epi layer 21 formed in n+ substrate 22. Substrate 22 provides structural support for the device. A p layer 23 is formed over epi layer 21. Contours 24 are formed in epi layer 21 and p layer 23 to build the mesa between the contours. The p-n junction is formed between p+ layer 23 and n− epi layer 21.

Planar and mesa processes impose certain limitations on the manufacturing process and design criteria that can affect the electrical parameters of the device. An important consideration is the behavior of the p-n junction under high voltage. A high voltage creates electric field fringing because the junction terminates at the device surface. Accordingly, silicon p-n junctions normally breakdown at the surface of the device. The fringing electric field reduces the device breakdown voltage. To compensate, guard rings or field plates are often used to spread out the fringing electric field.

Depending on the specific manufacturing steps, the planar process can have surface state limitations that degrade the reverse breakdown voltage and increase the p-n junction leakage current. The surface state limitations further restrict the level of breakdown voltage that can be obtained even if other design parameters are proper. The planar process typically requires deep junctions to decrease the radius of curvature of the diffused junction. However, the deep junction has the undesired effect of increasing the sidewall capacitance of the p-n junction and adds to the manufacturing cost.

In a mesa manufacturing process, photolithography and etching are used to define the p-n junction. Contouring the shape of the mesa and deep diffusion, e.g., 90-100 micrometers (μm), can improve the breakdown voltage as shown in FIG. 3, but adds complexity and cost to the manufacturing process. For example, the mesa process can take 200-300 hours. The removal of silicon to form the contours and mesa makes wafer handling problematic and leads to wafer breakage and yield loss.

The planar and mesa processes have used different types of passivation films to help maintain a stable reverse breakdown voltage. For example, a high temperature oxidation can be used to passivate the p-n junction, followed by additional thin passivation layers to obtain a stable junction. In adapting various passivation films, surface states and charges within the film must be closely monitored to prevent undesirable characteristics. The additional passivation layers require more handling that further leads to wafer breakage and contamination that can degrade the electrical parameters. The passivation films also add cost, complexity, and variation to the manufacturing process which can degrade the film characteristics, as well as the p-n junction. The potential for wafer breakage limits the use of large diameter wafers, which increases manufacturing costs.

Another deficiency is the relatively poor electrical stability when the semiconductor device is subjected to high temperature reverse bias (HTRB) at elevated temperature, such as 150-175 degrees centigrade (° C.). While surface passivation films may provide satisfactory results at lower operating conditions, long term high temperature stability is preferred as a measure of stability for the semiconductor device, especially for military and space applications.

In the manufacture of ICs, an isolation diffusion process is commonly used to make analog and digital circuits. The isolation diffusion process uses photolithography and etching to define the isolation surface area. The resolution of the photolithographic process defines the width of the isolation pattern. The isolation diffusion process imposes certain design limitations that affect the electrical parameters and die size, including the width of the isolation pattern, thickness of the epi or depth of the p-n junction, and resistivity that must be scaled to the desired voltage. In general, the higher the voltage, the higher the resistivity and the thicker the epi layer or deeper the p-n junction. The isolation diffusion process can cause lateral junction-spreading from all edges of the defining mask pattern at the surface of the die which imposes a volume space problem at the junction. The spreading extends laterally as the diffusion is driven downward to the substrate, which requires a substantial amount of silicon to isolate each active device area.

As semiconductor technology continues to advance, there is a need for higher breakdown voltage devices within the limitations of depletion-spread spacing. The need for higher breakdown voltage has been further restricted by the limitations of the planar and mesa technologies requiring much higher starting resistivity than needed. The mesa technology is restricted by the ability handle deep diffused p-n junctions and associated wet chemical etching used to define the p-n junction. The planar technology is restricted by the curvature of the p-n junction diffusion requiring deep diffusions and achieve 60-70% of theoretical breakdown voltage while giving much higher capacitance because of the sidewall effects of the deep junctions.

### SUMMARY OF THE INVENTION

A needs exist to provide a higher breakdown voltage with a shallower p-n junction. In one embodiment, the present invention is a method of making a semiconductor device comprising the steps of providing a substrate including a semiconductor material of a first conductivity type, forming a first layer including a semiconductor material of a second conductivity type in the substrate with a first boundary between the first layer and the semiconductor material of the first conductivity type, forming a first vertical trench through the first layer extending at least to the first boundary, and depositing a first insulating material in the first vertical trench.

In another embodiment, the present invention is a method of making a semiconductor device comprising the steps of providing a substrate including a semiconductor material of a first conductivity type, forming a first layer including a semiconductor material of a second conductivity type in the substrate, forming a first vertical trench through the first layer to a depth of less than 40 micrometers, and depositing a first insulating material in the first vertical trench.

In another embodiment, the present invention is a semiconductor device comprising a substrate including a semiconductor material of a first conductivity type. A first layer including a semiconductor material of a second conductivity type is formed in the substrate with a first boundary between the first layer and the semiconductor material of the first conductivity type. A first vertical trench is formed through the first layer extending at least to the first boundary. A first insulating material is deposited in the first vertical trench.

In another embodiment, the present invention is a semiconductor device comprising a substrate including a semiconductor material of a first conductivity type. A first layer including a semiconductor material of a second conductivity type is formed in the substrate. A first vertical trench is formed through the first layer to a depth of less than 40 micrometers. A first insulating material is deposited in the first vertical trench.

### BRIEF DESCRIPTION OF THE DRAWINGS

FIG. 1 illustrates a cross-sectional view of a conventional p-n junction diode formed by a planar process;

FIG. 2 is a conventional bipolar transistor formed by a planar process;

FIG. 3 is a conventional p-n junction diode formed by a mesa process;

FIG. 4 illustrates a PCB with different types of semiconductor packages mounted to its surface;

FIGS. 5a-5j illustrate a process of forming a discrete diode with a sealed trench junction termination;

FIG. 6 illustrates the discrete semiconductor device with a sealed trench junction termination;

FIGS. 7a-7b illustrate another process of forming a discrete diode with a sealed trench junction termination;

FIGS. 8a-8e illustrate a process of forming a discrete lateral bipolar transistor with a sealed trench junction termination;

FIG. 9 illustrates a discrete vertical bipolar transistor with a sealed trench junction termination;

FIG. 10 illustrates a discrete trench rectifier with a sealed trench junction termination;

FIG. 11 illustrates a discrete bidirectional trench TVS with a sealed trench junction termination;

FIG. 12 illustrates a discrete trench TVS with a sealed trench junction termination;

FIG. 13 illustrates a discrete trench SCR with a sealed trench junction termination;

FIG. 14 illustrates a discrete trench triode with a sealed trench junction termination;

FIG. 15 illustrates a discrete trench SCR with a sealed trench junction termination;

FIG. 16 illustrates a discrete trench triode with a sealed trench junction termination; and

FIG. 17 illustrates a discrete lateral bipolar transistor with a sealed trench junction termination.

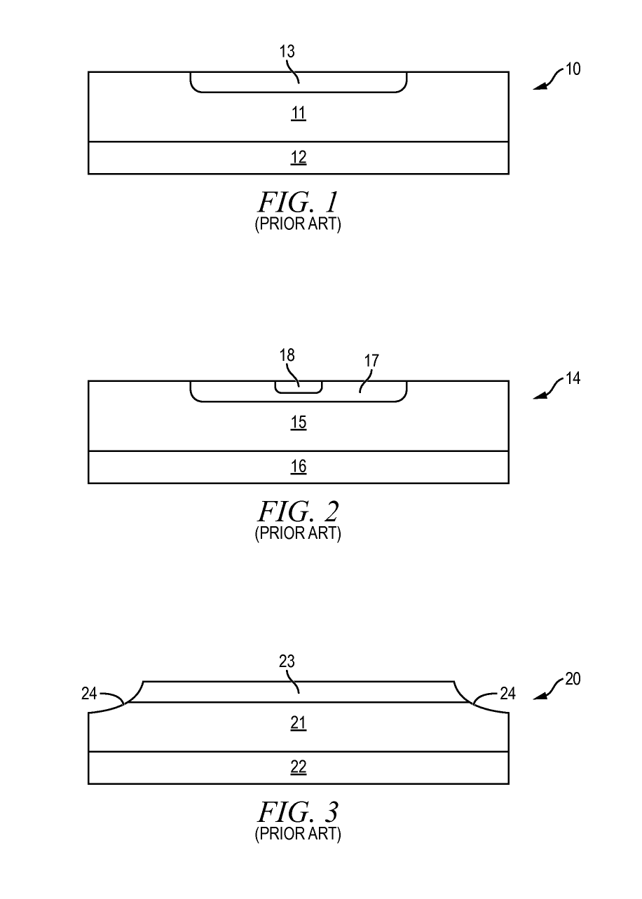

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices are generally manufactured using two complex manufacturing processes: front-end manufacturing and back-end manufacturing. Front-end manufacturing generally refers to formation of the semiconductor devices on the wafer. Each die contains one to hundreds or more of transistors and other active and passive devices performing one or more electrical functions. For a given wafer, each die from the wafer typically performs the same electrical function. Active electrical components, such as transistors and diodes, have the ability to control the flow of electrical current. By varying levels of doping and application of an electric field or base current, the transistor either promotes or restricts the flow of electrical current. Passive electrical components, such as capacitors, inductors, and resistors, create a relationship between voltage and current necessary to perform electrical circuit functions. The active and passive structures are electrically connected to form circuits, which enable the semiconductor device to perform high-speed calculations and other useful functions.

A semiconductor wafer includes an active surface having semiconductor devices disposed thereon, and a backside surface formed with bulk semiconductor material, e.g., silicon (Si). Active and passive devices can also be formed on the backside of the wafer. Active and passive components are formed over the active surface of the semiconductor wafer by a series of processing steps including layering, deposition, doping, photolithography, patterning, etching, and planarization. In the layering process, semiconductor materials are grown or deposited on the substrate by techniques involving thermal oxidation, nitridation, chemical vapor deposition (CVD), physical vapor deposition (PVD), electrolytic plating, electro-plating, electroless plating, evaporation, and sputtering. The doping process injects concentrations of dopant material by thermal diffusion, ion implantation, or other doping methods to modify the electrical conductivity of semiconductor material in active devices by dynamically changing the semiconductor material conductivity in response to an electric field or base current. Photolithography involves the masking of areas of the surface and etching away undesired material to form specific structures. A photoresist layer is typically used to isolate areas on the semiconductor wafer for etching. Each layer is patterned to form portions of active components, passive components, or electrical connections between components.

Back-end manufacturing refers to cutting or singulating the finished wafer into the individual semiconductor die and then packaging the semiconductor die for structural support and environmental isolation. To singulate the semiconductor die, the wafer is scored and broken along non-functional regions of the wafer called saw streets or scribes. The wafer can be singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and environmental protection. The finished package is inserted into an electrical system and the functionality of the semiconductor device is made available to the other system components.

Semiconductor devices come in a variety of package types and perform specific functions. Some common types of semiconductor devices are ICs and discrete devices, such as transistors, diodes, rectifiers, TVS, SCR, and thyristors. Discrete semiconductor devices perform specific functions, such as signal rectification and power transfer.

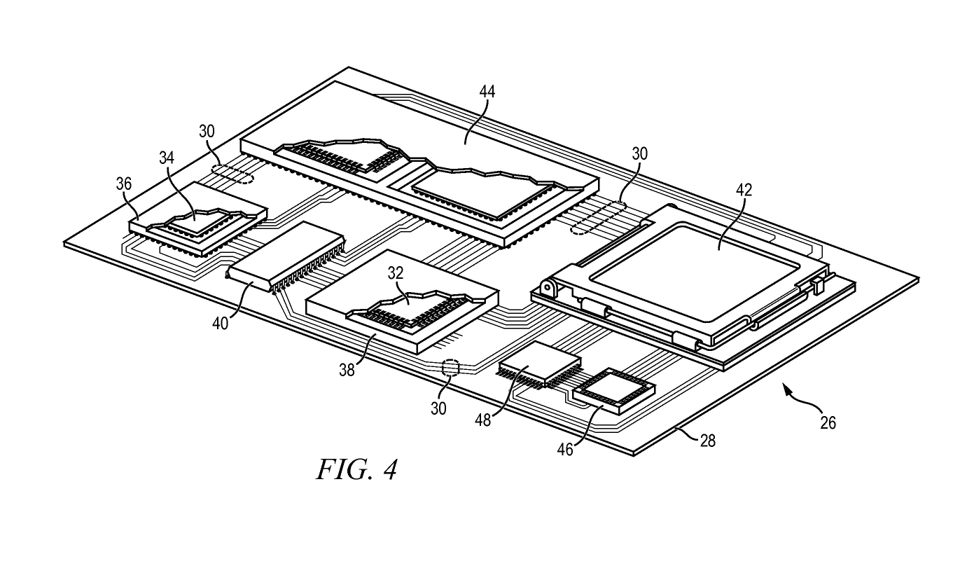

FIG. 4 illustrates electronic device 26 having a chip carrier substrate or printed circuit board (PCB) 28 with a plurality of semiconductor packages mounted on its surface. Electronic device 26 can have one type of semiconductor package, or multiple types of semiconductor packages, depending on the application. The different types of semiconductor packages are shown in FIG. 4 for purposes of illustration.

Electronic device 26 can be a stand-alone system that uses the semiconductor packages to perform one or more electrical functions. Alternatively, electronic device 50 can be a subcomponent of a larger system. For example, electronic device 26 can be part of a cellular phone, personal digital assistant (PDA), digital video camera (DVC), or other electronic communication device. Alternatively, electronic device 26 can be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. Miniaturization and weight reduction are essential for the products to be accepted by the market. The distance between semiconductor devices must be decreased to achieve higher density.

In FIG. 4, PCB 28 provides a general substrate for structural support and electrical interconnect of the semiconductor packages mounted on the PCB. Conductive signal traces 30 are formed over a surface or within layers of PCB 28 using evaporation, electrolytic plating, electroless plating, screen printing, or other suitable metal deposition process. Signal traces 30 provide for electrical communication between each of the semiconductor packages, mounted components, and other external system components. Traces 30 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 32 and flipchip 34, are shown on PCB 28. Additionally, several types of second level packaging, including ball grid array (BGA) 36, bump chip carrier (BCC) 38, dual in-line package (DIP) 40, land grid array (LGA) 42, multi-chip module (MCM) 44, quad flat non-leaded package (QFN) 46, and quad flat package 48, are shown mounted on PCB 28. Depending upon the system requirements, any combination of semiconductor packages, configured with any combination of first and second level packaging styles, as well as other electronic components, can be connected to PCB 28. In some embodiments, electronic device 26 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

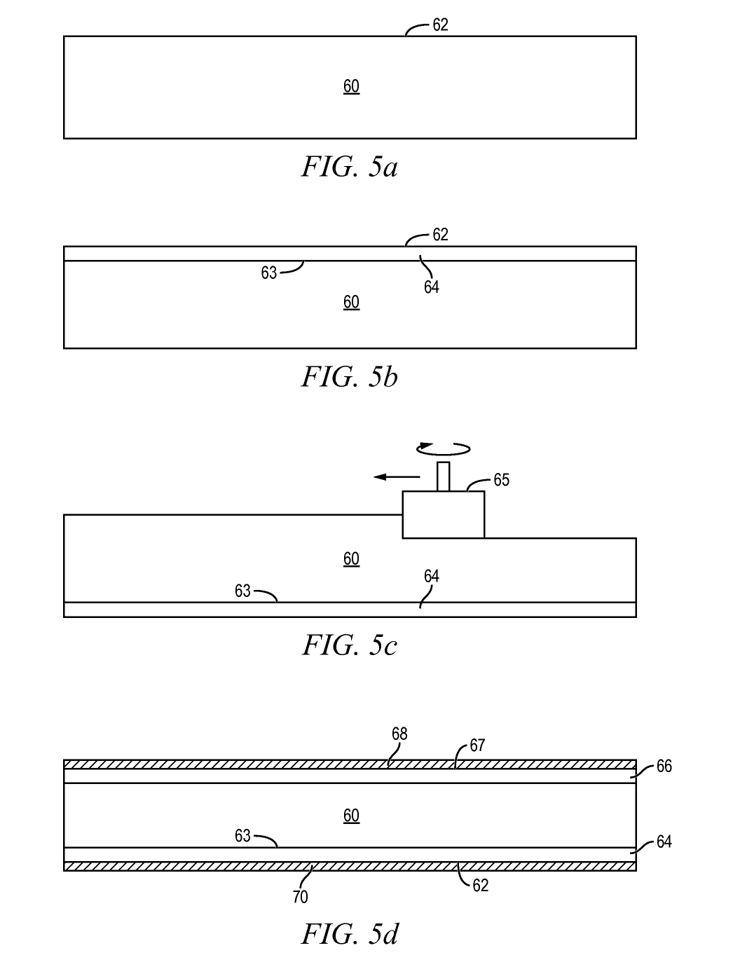

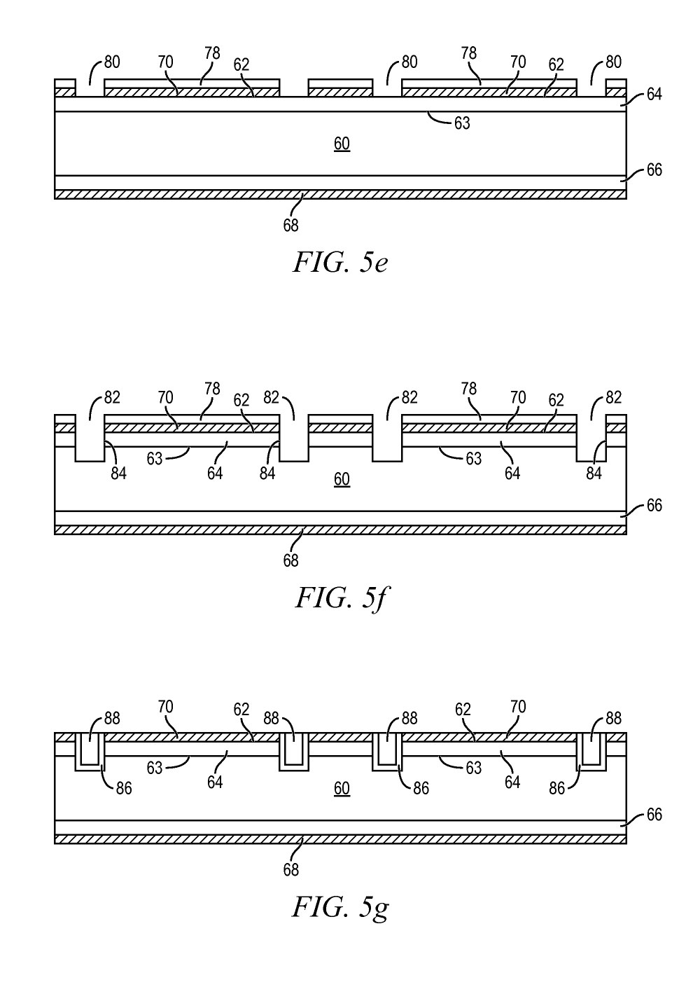

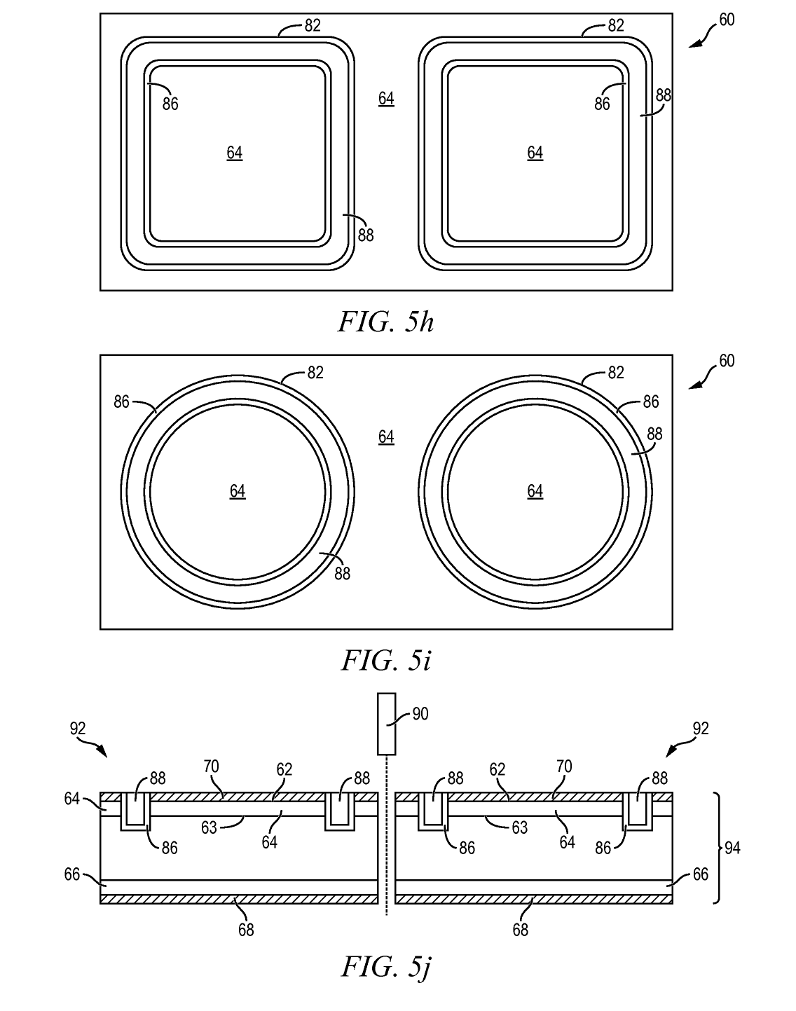

FIGS. 5a-5j illustrate, in relation to FIG. 4, a process of forming a discrete semiconductor device containing a diode having a shallow p-n junction with a sealed trench termination to provide improved electrical characteristics. FIG. 5a shows a portion of semiconductor substrate or wafer 60 containing silicon, germanium, aluminum phosphide, aluminum arsenide, gallium arsenide, gallium nitride, indium phosphide, silicon carbide, or other bulk semiconductor material for structural support. Semiconductor wafer 60 is doped with phosphorus, arsenic, or antimony to have an n-type conductivity with a resistivity between 0.5 to 500 ohms-cm.

A plurality of doped semiconductor layers and regions are formed in substrate 60 using semiconductor photolithography or implantation manufacturing processes, such as layering, patterning, doping, and heat treatment. In the layering process, materials are grown or deposited on the substrate by techniques involving thermal oxidation, nitridation, PVD, CVD, evaporation, and sputtering. The doping process injects concentrations of dopant material, i.e., n-type semiconductor material or p-type semiconductor material, by thermal diffusion or ion implantation and thermal anneal. Patterning involves use of photolithography to mask areas of the surface and etch away undesired material to form specific structures.

More specifically, surface 62 of semiconductor wafer 60 is implanted with p-type dopant, such as boron, aluminum, gallium, or indium, to a surface concentration of 1E19 atoms/cm³, using a sheet-type doping process to form p layer 64, as shown in FIG. 5b. Semiconductor wafer 60 is heated to 1000-1250° C. to drive the boron or other dopant into surface 62 and form a p-n junction 63 at the desired depth, i.e., at the boundary where p− type dopant charge is equal to and opposite of the n-type dopant charge. In one embodiment, semiconductor wafer 60 is heated for an initial deposition of boron at 1100° C. for 60-90 minutes. Semiconductor wafer 60 is then heated to 1200° C. for 2-8 hours to drive the boron in p layer 64 further into the substrate and achieve the desired depth for p-n junction 63. The sheet diffusion forms a shallow and substantially uniform depth p layer 64 in semiconductor wafer 60, e.g., p-n junction depth of 40 μm or less. In another embodiment, the shallow p-n junction 63 has a depth of 15-20 μm or less. The shallow p-n junction depth reduces the time at high temperature required to produce p layer 64 and reduces sidewall capacitance. Alternatively, the p-type dopant is deposited by ion implantation. An oxidation layer can be formed as a protective layer over p layer 64. The p layer 64 operates as an anode of the discrete diode and n− wafer 60 operates as a cathode of the discrete diode.

In FIG. 5c, semiconductor wafer 60 is inverted and undergoes a grinding operation with grinder 65. Grinder 65 removes a portion of bases material of semiconductor wafer 60. A chemical etch, polishing, wet or dry chemical mechanical polishing (CMP), or other suitable process can also be used to remove base substrate material, including mechanical damage and backgrinding damage, and to planarize semiconductor wafer 60. Removal of excess base substrate material from semiconductor wafer 60 results in a planar back surface and reduced thickness of the wafer, e.g., 300 μm or less. The grinding operation for semiconductor wafer 60 is useful in applications requiring reduced package thickness.

FIG. 5d shows an optional diffusion of an n-type dopant into surface 67 of semiconductor wafer 60 opposite p layer 64 to form n+ layer 66 as part of the cathode of the diode structure. The n-type dopant can be phosphorus, arsenic, or antimony. In one embodiment, the diffusion uses a phosphorus dopant to provide an enhanced ohmic contact with aluminum metallization. An electrically conductive layer 68 is formed over n+ layer 66 and electrically conductive layer 70 is formed over p layer 64 using PVD, CVD, electrolytic plating, electroless plating process, or other suitable metal deposition process. Conductive layers 68 and 70 can be one or more layers of Al, Cu, Sn, Ni, Au, Ag, Ti, or other suitable electrically conductive material. Conductive layers 68 and 70 operate as an electrical contact to n+ layer 66 and p layer 64, respectively.

In FIG. 5e, an insulating or passivation layer 78 is formed over conductive layer 70 using PVD, CVD, printing, lamination, spin coating, spray coating, sintering or thermal oxidation. The insulating layer 78 contains one or more layers of SiO2, silicon nitride (Si3N4), silicon oxynitride (SiON), tantalum pentoxide (Ta2O5), aluminum oxide (Al2O3), or other material having similar insulating and structural properties. A plurality of openings 80 is formed through insulating layer 78 and conductive layer 70 by an etching process to expose p layer 64.

In FIG. 5f, trench 82 is formed in semiconductor wafer 60 aligned with openings 80 and extending through p layer 64 into the substrate, i.e., at least to or past p-n junction 63 defined as the interface between p layer 64 and n− substrate 60. In one embodiment, trench 82 is formed using argon as an ionization gas with sulfur hexaflouride (SF6) etchant or other anisotropic type etchant to create vertical sidewalls. Conductive layer 70 can serve as a mask during the etching step. Trench 82 can be formed without opening 80. Trench 82 surrounds p-n junction. Sidewalls 84 of trench 82 are substantially vertical with respect to surface 62 and substantially square or orthogonal with respect to p-n junction 63. Trench 82 extends at least as deep as or deeper than the physical p-n junction 63. In one embodiment, trench 82 has a depth of 21 μm and p-n junction 63 has a depth of 20 μm. In plan view, trench 82 is circular, oval, rounded, rectangular, hexagon, or other shape to surround p-n junction 63 with a smooth, vertical wall, see FIGS. 5h-5i.

In FIG. 5g, trench 82 is lined or coated with an insulating layer 86, such as thermal oxide, SiO2, or other material having similar properties, in an oxygen atmosphere at a temperature between 800-1150° C. The insulating layer 86 seals the perimeter of p-n junction 63 from contamination and provides long-term stability for the semiconductor device. Trench 82 is filled with an insulating material 88 over insulating layer 86, such as Si3N4, SiON, SiO2, Ta2O5, ZrO2, Al2O3, polysilicon, amorphous silicon, semi-insulating polysilicon, dielectric, or other material having similar properties. Alternatively, oxynitride is deposited into an unlined trench to protect p-n junction 63 from contamination and increase reliability. The shallow p-n junction 63 terminated with a vertical walled trench 82 filled with insulating material 86-88 operates as a vertical boundary and high voltage termination surrounding the p-n junction. In particular, the vertical walled trench 82 as formed by anisotropic etch and filled with insulating material 86-88 increases breakdown voltage of the discrete diode (to 1600 volts or more) by nature of the vertical depletion spread along the vertical insulating trench. The vertical walled trench 82 filled with insulating material 86-88 extending at least to the shallow p-n junction 63 significantly reduces time and cost during manufacturing of semiconductor wafer 60, e.g., trench 82 can be formed in about 8 hours or less.

FIG. 5h shows a plan view of a portion of semiconductor wafer 60 including two trenches 82 each around a discrete diode and having a rectangular shape with rounded corners formed through p layer 64 into the substrate. Trench 82 is lined with insulating layer 86 and filled with insulating material 88. FIG. 5i shows a plan view of a portion of semiconductor wafer 60 including two trenches 82 each around a discrete diode and having a circular or oval shape formed through p layer 64 into the substrate. Trenches 82 are lined with insulating layer 86 and filled with insulating material 88. In another embodiment, trench 82 can have an oval, rounded, curved, polygonal, or other regular or irregular shape around each discrete diode.

In FIG. 5j, semiconductor wafer 60 is singulated using a saw blade or laser cutting tool 90 into individual semiconductor die 92 each containing a discrete diode 94 surrounded by insulating trench 82-88. Semiconductor wafer 60 can be singulated through trench 82 provided the internal sidewall of the trench remains vertical.

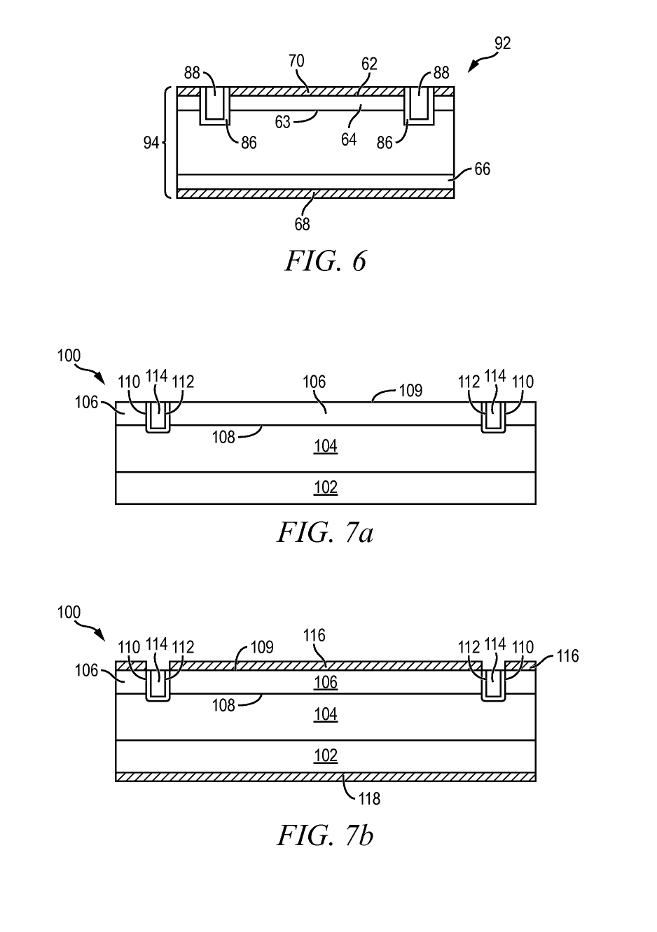

FIG. 6 shows semiconductor die 92 after singulation. Discrete diode 94 is formed monolithically within semiconductor die 92. The shallow p-n junction 63 of diode 94 is 40 μm or less and terminates with trench 82 having vertical sidewall 84 lined with insulating layer 86 and filled with insulating material 88 to define the horizontal boundary of the p-n junction as a vertical plane extending at least down to or past the physical p-n junction 63 between p layer 64 and n− substrate 60. The vertical insulation-filled trench 82-88 increases breakdown voltage and reduces production time for semiconductor die 92. Any electric field imposed by a high voltage terminates at the horizontal boundary established by insulating trench 82-88. Accordingly, insulating filled trench 82-88 functions as a sealed trench junction termination, which provides a high breakdown voltage for the device. The shallow p-n junction 63 reduces processing time and provides an unexpectedly high breakdown voltage when surrounded by the vertical insulating trench 82-88. For example, insulating trench 82-88 to the shallow p-n junction 63 can be formed in 8 hours while providing a breakdown voltage of 1600 volts or more. The insulating trench 82-88 uses a small silicon area for the sealed trench junction termination, while providing mechanical strength for the wafer during subsequent handling in the manufacturing process.

By eliminating the p-n junction termination at the surface of the semiconductor body, as well as the junction curvature, diode 94 has significantly improved electrical characteristics. For example, surface effects on the leakage current of p-n junction 63 are substantially reduced. The reverse breakdown voltage is higher without significantly increasing the size of the die and complexity of the manufacturing steps. Further, the reverse breakdown voltage of p-n junction 63 is more consistent across the wafer. By forming a shallow p-n junction, the sidewall capacitance is reduced which increases the frequency response of the device for high frequency applications. A semiconductor device having the insulating trench offers improved reliability, wafer strength, die density per wafer, breakdown voltage, high temperature stability, less risk of breakage or contamination, and overall manufacturing yield.

FIGS. 7a-7b illustrate a cross-sectional view of another embodiment of a discrete semiconductor device containing diode 100 with a p-n junction. FIG. 7a shows a portion of semiconductor substrate or wafer 102 containing silicon, germanium, aluminum phosphide, aluminum arsenide, gallium arsenide, gallium nitride, indium phosphide, silicon carbide, or other bulk semiconductor material for structural support. Semiconductor wafer 102 is doped with phosphorus, arsenic, or antimony to have an n-type conductivity with a resistivity between 0.5 to 500 ohms-cm.

A plurality of doped semiconductor layers and regions are formed in wafer 102 using semiconductor photolithography or implantation manufacturing processes, such as layering, patterning, doping, and heat treatment. In the layering process, materials are grown or deposited on the substrate by techniques involving thermal oxidation, nitridation, PVD, CVD, evaporation, and sputtering. The doping process injects concentrations of dopant material, i.e., n-type semiconductor material or p-type semiconductor material, by thermal diffusion or ion implantation and thermal anneal. Patterning involves use of photolithography to mask areas of the surface and etch away undesired material to form specific structures.

Discrete diode 100 is formed monolithically on n+ wafer 102, which provides structural support for the device. More specifically, an n− epi layer 104 is formed in n+ wafer 102. The n-type semiconductor dopant can be phosphorus, arsenic, or antimony. A p layer 106 is formed in semiconductor wafer 102 over n− epi layer 104. The p-type semiconductor dopant can be boron, aluminum, gallium, or indium. The p-n junction 108 is defined by p layer 106 and n− epi layer 104, i.e., at the boundary where p-type dopant charge is equal to and opposite of the n-type dopant charge. The p-n junction 108 in diode 100 is shallow, e.g., less than 40 μm from surface 109 of p layer 106. In another embodiment, p-n junction 108 is 20 μm or less from surface 109. Semiconductor wafer 102, epi layer 104, and layer 106 can be formed with respectively opposite conductivity types, i.e., p+ substrate, p− epi layer, and n layer.

A trench 110 is formed through p layer 106 and extends at least to junction or boundary 108 with n− epi layer 104, or into n− epi layer 104, using a photolithographic and anisotropic etching process, similar to FIG. 5f. For example, a photoresist layer is deposited over surface 109 to establish an area that surrounds p-n junction 108 formed by p layer 106 and n− epi layer 104. The unmasked areas are subjected to the anisotropic etch to form vertical trench 110 to a predetermined depth. Trench 110 can be circular, oval, rounded, curved, polygonal, or other regular or irregular shape around each discrete diode 100, similar to FIGS. 5h-5i.

Trench 110 is made at least as deep as or deeper than the physical p-n junction 108 to provide a high voltage termination of the junction. In one embodiment, trench 110 has a depth of 21 μm and p-n junction 108 has a depth of 20 μm. The sidewalls of trench 110 are substantially vertical with respect to surface 109 of p layer 106 and substantially square or orthogonal with respect to p-n junction 108 to form a vertical boundary surrounding the p-n junction between p layer 106 and n− epi layer 104.

Trench 110 is lined or coated with an insulating layer 112, such as thermal oxide, SiO2, or other material having similar properties, in an oxygen atmosphere at a temperature between 800-1150° C., similar to FIG. 5g. The insulating layer 112 seals the perimeter of p-n junction 108 from contamination and provides long-term stability for diode 100. Trench 110 is filled with an insulating material 114, such as Si3N4, SiON, SiO2, Ta2O5, ZrO2, Al2O3, polysilicon, amorphous silicon, and semi-insulating polysilicon, dielectric, or other material having similar properties. The insulation-filled trench 110-114 is planarized using etch-back or CMP to be even with surface 109 of p layer 106 in order to form one or more metallization layers which make a low resistance ohmic electrical contact with the opposing regions of diode 100.

The shallow p-n junction 108 of diode 100 is 40 μm or less and terminates with trench 110 having vertical sidewalls lined with insulating layer 112 and filled with insulating material 114 to define the horizontal boundary of the p-n junction as a vertical plane extending at least down to or past the physical p-n junction 108 between p layer 106 and n− epi layer 104. The vertical insulation-filled trench 110-114 increases breakdown voltage and reduces production time for diode 100. Any electric field imposed by a high voltage terminates at the horizontal boundary established by insulating trench 110-114. Accordingly, trench 110-114 functions as a sealed trench junction termination, which provides a high breakdown voltage for the device. The shallow p-n junction 108 reduces processing time and provides an unexpectedly high breakdown voltage when surrounded by the vertical insulating trench 110-114. For example, insulating trench 110-114 to the shallow p-n junction 108 can be formed in 8 hours while providing a breakdown voltage of 1600 volts or more. The insulating trench 110-114 uses a small silicon area for the sealed trench junction termination, while providing mechanical strength for the wafer during subsequent handling in the manufacturing process.

By eliminating the p-n junction termination at the surface of the semiconductor body, as well as the junction curvature, diode 100 has significantly improved electrical characteristics. For example, surface effects on the leakage current of p-n junction 108 are substantially reduced. The reverse breakdown voltage is higher without increasing the size of the die and complexity of the manufacturing steps. Further, the reverse breakdown voltage of p-n junction 108 is more consistent across the wafer. By forming a shallow p-n junction, the sidewall capacitance is reduced which increases the frequency response of the device for high frequency applications. A semiconductor device having the insulating trench offers improved reliability, wafer strength, die density per wafer, breakdown voltage, high temperature stability, less risk of breakage or contamination, and overall manufacturing yield.

In FIG. 7b, an electrically conductive layer 116 is formed over p layer 106 and electrically conductive layer 118 is formed over n+ wafer 102 using PVD, CVD, electrolytic plating, electroless plating process, or other suitable metal deposition process. Conductive layers 116 and 118 can be one or more layers of Al, Cu, Sn, Ni, Au, Ag, Ti, or other suitable electrically conductive material. Conductive layers 116 and 118 operate as an electrical contact to p layer 106 and n+ wafer 102, respectively. Semiconductor wafer 102 is singulated using a saw blade or laser cutting tool into individual semiconductor die each containing a discrete diode 100 surrounded by insulating trench 110-114.

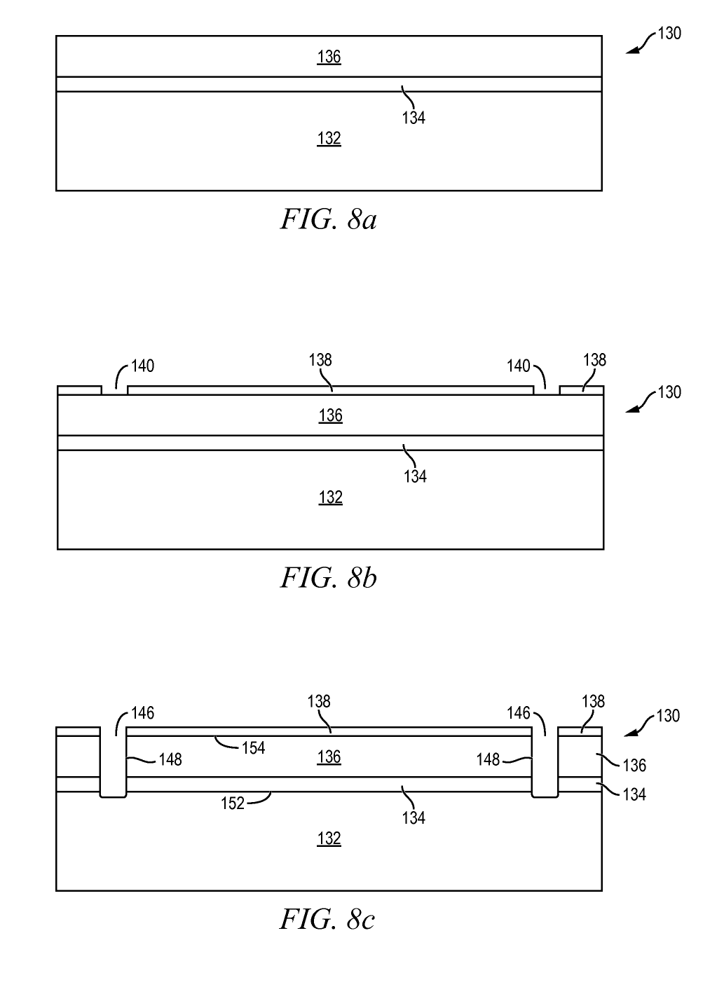

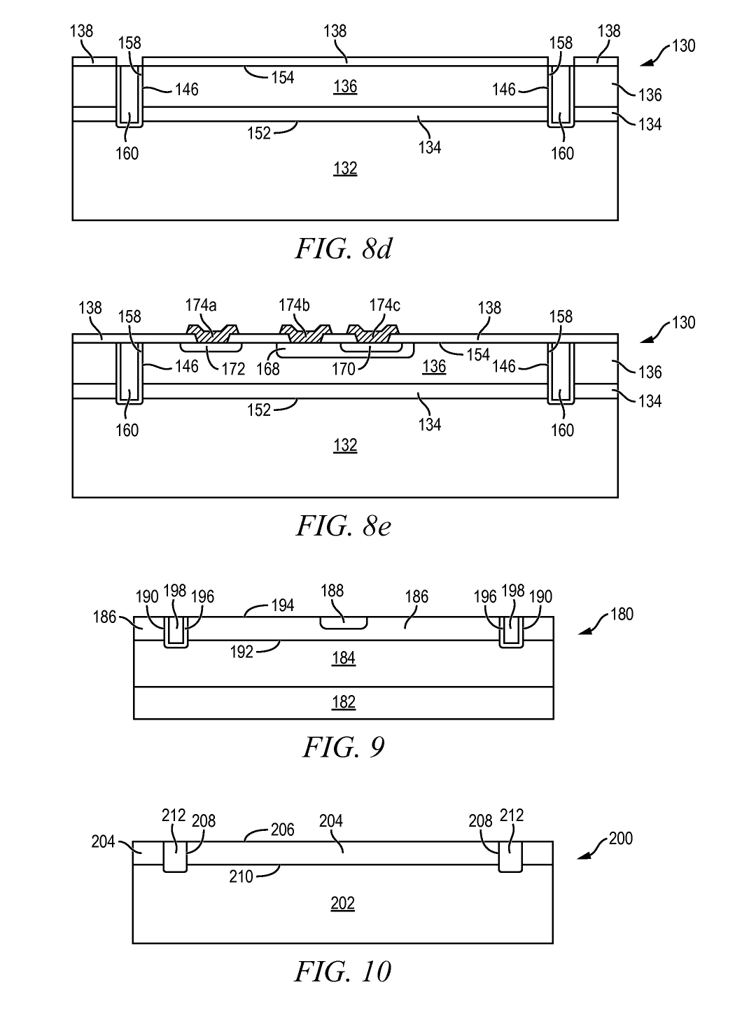

FIGS. 8a-8e illustrate, in relation to FIG. 4, a process of forming an IC or semiconductor device 130 with a sealed trench termination to provide improved electrical characteristics. While the process flow is directed to a lateral bipolar transistor, a similar process can be used to form other IC semiconductor devices. FIG. 8a shows a portion of semiconductor substrate or wafer 132 containing silicon, germanium, aluminum phosphide, aluminum arsenide, gallium arsenide, gallium nitride, indium phosphide, silicon carbide, or other bulk semiconductor material for structural support. Semiconductor wafer 132 is doped with boron, aluminum, gallium, or indium to have a p-type conductivity with a resistivity between 0.5 to 500 ohms-cm.

A plurality of doped semiconductor layers and regions are formed in substrate 132 using semiconductor photolithography or implantation manufacturing processes, such as layering, patterning, doping, and heat treatment. In the layering process, materials are grown or deposited on the substrate by techniques involving thermal oxidation, nitridation, PVD, CVD, evaporation, and sputtering. The doping process injects concentrations of dopant material, i.e., n-type semiconductor material or p-type semiconductor material, by thermal diffusion or ion implantation and thermal anneal. Patterning involves use of photolithography to mask areas of the surface and etch away undesired material to form specific structures.

More specifically, semiconductor wafer 132 is implanted with n-type dopant, typically phosphorus, arsenic, or antimony, using a sheet-type doping process to form n+ buried layer 134. An n− epi layer 136 is formed in semiconductor wafer 132 over n+ buried layer 134 by sheet-type doping or ion implantation of an n-type dopant, such as phosphorus, arsenic, or antimony. The n+ buried layer 134 provides electrical isolation of semiconductor device 130 and reduces pattern washout effects that may occur on Si <111> and Si <100> crystal orientation substrates during formation of n− epi layer 136.

In FIG. 8b, an insulating or passivation layer 138 is formed over n− epi layer 136 using PVD, CVD, printing, lamination, spin coating, spray coating, sintering or thermal oxidation. The insulating layer 138 contains one or more layers of SiO2, Si3N4, SiON, Ta2O5, Al2O3, or other material having similar insulating and structural properties. A plurality of openings 140 is formed through insulating layer 138 by an etching process to expose n− epi layer 136.

In FIG. 8c, trench 146 is formed in semiconductor wafer 132 aligned with openings 140 and extending through n− epi layer 136 and n+ buried layer 134 into the substrate, i.e., at least to or past junction 152 defined as the interface between p substrate 132 and n+ buried layer 134. In one embodiment, trench 146 is formed using argon as an ionization gas with SF6 etchant or other anisotropic type etchant to create vertical sidewalls 148. In particular, trench 146 has substantially vertical sidewalls 148 to form a vertical boundary surrounding junction 152 between p substrate 132 and n+ buried layer 134. Sidewalls 148 of trench 146 are substantially vertical with respect to surface 154 and substantially square or orthogonal with respect to junction 152 to provide a vertical termination of the junction. Trench 146 extends at least as deep as or deeper than physical junction 152.

In FIG. 8d, trench 146 is lined or coated with an insulating layer 158, such as thermal oxide, SiO2, or other material having similar properties, in an oxygen atmosphere at a temperature between 800-1150° C. The insulating layer 158 seals the perimeter of the area above junction 152 from contamination and provides long-term stability for the semiconductor device. Trench 146 is filled with an insulating material 160, such as Si3N4, SiON, SiO2, Ta2O5, ZrO2, Al2O3, polysilicon, amorphous silicon, semi-insulating polysilicon, dielectric, or other material having similar properties. Alternatively, oxynitride is deposited into an unlined trench to protect the area above junction 152 from contamination and increase reliability.

In another embodiment, the insulating-filled trench 146, 158-160 is formed without insulating layer 138 and opening 140. The insulation-filled trench 146, 158-160 is planarized using etch-back or CMP to be even with the surface of n− epi layer 136 in order to form metallization layers which make a low resistance ohmic electrical contact with regions of semiconductor device 130.

The junction 152 terminated with a vertical walled trench 146 filled with insulating material 158-160 operates as a vertical boundary and high voltage termination surrounding the junction between p substrate 132 and n+ buried layer 134. In particular, the vertical walled trench 146 as formed by anisotropic etch and filled with insulating material 158-160 increases breakdown voltage of the semiconductor device 130 (to 1600 volts or more) by nature of the vertical depletion spread along the vertical insulating trench. The vertical walled trench 146 filled with insulating material 158-160 extending at least to junction 152 significantly reduces time and cost during manufacturing of semiconductor wafer 130, e.g., trench 146 can be formed in about 8 hours or less. Trench 146 can be circular, oval, rounded, curved, polygonal, or other regular or irregular shape, similar to FIGS. 5h-5i.

In FIG. 8e, vertical isolating filled trench 146, 158-160 is covered with insulating layer 138. A portion of insulating layer 138 is removed by an etching process to expose portions of n− epi layer 136. A p base well 168 is formed in n− epi layer 136 by diffusion or implantation of p-type dopant. The p base well 168 operates as a base region of the transistor. An n+ region 170 is formed in p base well 168 by diffusion or implantation of n-type dopant. The n+ region 170 operates as an emitter region of the transistor. An n+ region 172 is formed in n− epi layer 136 for electrical contact. The n− epi layer 136 operates as a collector region of the transistor. An electrically conductive layer 174 is formed over n+ region 172, p base well 168, and n+ region 170 using PVD, CVD, electrolytic plating, electroless plating process, or other suitable metal deposition process. Conductive layer 174 can be one or more layers of Al, Cu, Sn, Ni, Au, Ag, Ti, or other suitable electrically conductive material. Portions 174a, 174b, and 174c of conductive layer 174 are electrically isolated to form contacts to the collector, base, and emitter of the bipolar transistor, respectively.

Semiconductor device 130 terminates with trench 146 having vertical sidewalls lined with insulating layer 158 and filled with insulating material 160 to define the horizontal boundary as a vertical plane extending at least down to or past the physical junction 152 between p substrate 132 and n+ buried layer 134 to give the semiconductor device significantly improved electrical characteristics. The vertical insulation-filled trench 146, 158-160 increases breakdown voltage and reduces production time for semiconductor device 130. Any electric field imposed by a high voltage terminates at the horizontal boundary established by insulating trench 146, 158-160. Accordingly, insulating trench 146, 158-160 functions as a sealed trench junction termination, which provides a high and uniform breakdown voltage across the device while reducing processing time without increasing the size of the die and complexity of the manufacturing steps. Surface effects on the leakage current around junction 152 are substantially reduced. The sidewall capacitance is reduced which increases the frequency response of semiconductor device 130 for high frequency applications. The insulating trench 146, 158-160 uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

FIG. 9 illustrates a discrete vertical trench bipolar transistor 180 formed monolithically on semiconductor wafer or substrate 182. Semiconductor wafer 182 contains silicon, germanium, aluminum phosphide, aluminum arsenide, gallium arsenide, gallium nitride, indium phosphide, silicon carbide, or other bulk semiconductor material for structural support. Semiconductor wafer 182 is doped with phosphorus, arsenic, or antimony to have n+ conductivity with a resistivity between 0.5 to 500 ohms-cm.

A plurality of doped semiconductor layers and regions are formed in semiconductor wafer 182 using semiconductor photolithography or implantation manufacturing processes, such as layering, patterning, doping, and heat treatment. An n− epi layer 184 is formed in semiconductor wafer 182. The n− epi layer 184 operates as a collector of bipolar transistor 180. A p− layer 186 is formed over n− epi layer 184 by diffusion or ion implantation of a p-type dopant, such as boron, aluminum, gallium, or indium. The p− layer 186 is formed at a shallow depth to reduce the time or temperature required for doping. In one embodiment, p-type dopant is spun onto the surface of semiconductor wafer 182 and then heated in a furnace to 1000-1250° C. for 8 hours or less to drive the p-type dopant into the wafer surface to a shallow depth of 40 μm or less (or 20 μm or less) and form p− layer 186. The p− layer 186 operates as a base region of bipolar transistor 180. A p+ region can be formed in p− layer 186 for electrical contact. An n region 188 is formed in p− layer 186 by diffusion or ion implantation of an n-type dopant, such as phosphorus, arsenic, or antimony. The n region 188 operates as an emitter region of bipolar transistor 180. Substrate 182, epi layer 184, layer 186, and region 188 can be formed with respectively opposite conductivity types.

A trench 190 is formed in semiconductor wafer 182 extending through p− layer 186, i.e., at least to or past junction 192 defined as the interface between p− layer 186 and n− epi layer 184. In one embodiment, trench 190 is formed using argon as an ionization gas with SF6 etchant or other anisotropic type etchant to create vertical sidewalls. In particular, trench 190 has substantially vertical sidewalls to form a vertical boundary surrounding junction 192. The sidewalls of trench 190 are substantially vertical with respect to surface 194 and substantially square or orthogonal with respect to junction 192 to provide a vertical termination of the junction. Trench 190 extends at least as deep as or deeper than physical junction 192.

Trench 190 is lined or coated with an insulating layer 196, such as thermal oxide, SiO2, or other material having similar properties, in an oxygen atmosphere at a temperature between 800-1150° C. The insulating layer 196 seals the perimeter of the area above junction 192 from contamination and provides long-term stability for the semiconductor device. Trench 190 is filled with an insulating material 198, such as Si3N4, SiON, SiO2, Ta2O5, ZrO2, Al2O3, polysilicon, amorphous silicon, semi-insulating polysilicon, dielectric, or other material having similar properties. Alternatively, oxynitride is deposited into an unlined trench to protect the area above junction 192 from contamination and increase reliability.

The insulation-filled trench is planarized using etch-back or CMP to be even with surface 194 in order to form metallization layers which make low resistance ohmic electrical contact with regions of bipolar transistor 180. An electrically conductive layer is formed over n region 188, p− layer 186, and n+ substrate 182 as contacts to the emitter, base, and collector of bipolar transistor 180, similar to FIG. 8e.

The junction 192 terminated with a vertical walled trench 190 filled with insulating material 196-198 operates as a vertical boundary and high voltage termination surrounding the junction between p− layer 186 and n− epi layer 184. In particular, the vertical walled trench 190 as formed by anisotropic etch and filled with insulating material 196-198 increases breakdown voltage of the semiconductor device (to 1600 volts or more) by nature of the vertical depletion spread along the vertical insulating trench. The vertical walled trench 190 filled with insulating material 196-198 extending at least to junction 192 significantly reduces time and cost during manufacturing of semiconductor wafer 182, e.g., trench 190 can be formed in about 8 hours or less. Trench 190 can be circular, oval, rounded, curved, polygonal, or other regular or irregular shape, similar to FIGS. 5h-5i.

Bipolar transistor 180 terminates with trench 190 having vertical sidewalls lined with insulating layer 196 and filled with insulating material 198 to define the horizontal boundary as a vertical plane extending at least down to or past the physical junction 192 between p− layer 186 and n− epi layer 184 to give the semiconductor device significantly improved electrical characteristics. The vertical insulation-filled trench 190, 196-198 increases breakdown voltage and reduces production time for bipolar transistor 180. Any electric field imposed by a high voltage terminates at the horizontal boundary established by insulating trench 190, 196-198. Accordingly, insulating trench 190, 196-198 functions as a sealed trench junction termination, which provides a high and uniform breakdown voltage across the device while reducing processing time without increasing the size of the die and complexity of the manufacturing steps. Surface effects on the leakage current around junction 192 are substantially reduced. The sidewall capacitance is reduced which increases the frequency response of bipolar transistor 180 for high frequency applications. The insulating trench 190, 196-198 uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

FIG. 10 illustrates a discrete trench rectifier 200 formed monolithically on semiconductor wafer or substrate 202. Semiconductor wafer 202 contains silicon, germanium, aluminum phosphide, aluminum arsenide, gallium arsenide, gallium nitride, indium phosphide, silicon carbide, or other bulk semiconductor material for structural support. Semiconductor wafer 182 is doped with phosphorus, arsenic, or antimony to have n conductivity with a resistivity between 0.5 to 500 ohms-cm.

A plurality of doped semiconductor layers and regions are formed in semiconductor wafer 202 using semiconductor photolithography or implantation manufacturing processes, such as layering, patterning, doping, and heat treatment. A p layer 204 is formed in surface 206 of semiconductor wafer 202 by diffusion or ion implantation of a p-type dopant, such as boron, aluminum, gallium, or indium. In one embodiment, p-type dopant is spun onto surface 206 of semiconductor wafer 202 and then heated in a furnace to 1000-1250° C. for 8 hours or less to drive the p-type dopant to a shallow depth of 40 μm or less (or 20 μm or less) and form p layer 204. Substrate 202 and layer 204 can be formed with respectively opposite conductivity types.

A trench 208 is formed in semiconductor wafer 202 extending through p layer 204, i.e., at least to or past junction 210 defined as the interface between p layer 204 and n substrate 202. In one embodiment, trench 208 is formed using argon as an ionization gas with SF6 etchant or other anisotropic type etchant to create vertical sidewalls. In particular, trench 208 has substantially vertical sidewalls to form a vertical boundary surrounding junction 210. The sidewalls of trench 208 are substantially vertical with respect to surface 206 and substantially square or orthogonal with respect to junction 210 to provide a vertical termination of the junction. Trench 208 extends at least as deep as or deeper than physical junction 210. Trench 208 is filled with an insulating material 212, such as Si3N4, SiON, SiO2, Ta2O5, ZrO2, Al2O3, polysilicon, amorphous silicon, semi-insulating polysilicon, dielectric, or other material having similar properties.

Trench 208 can be lined or coated with a thermal oxide layer, such as SiO2, in an oxygen atmosphere at a temperature between 800-1150° C. The lining or coating seals the perimeter of the p-n junction from contamination and provides long-term stability for trench rectifier 200. The insulation-filled trench is planarized using etch-back or CMP to be even with surface 206 in order to form metallization layers which make low resistance ohmic electrical contact with regions of trench rectifier 200. An electrically conductive layer is formed over p layer 204 and n substrate 202 as contacts to trench rectifier 200, similar to FIG. 5d.

The junction 210 terminated with a vertical walled trench 208 filled with insulating material 212 operates as a vertical boundary and high voltage termination surrounding the junction between p layer 204 and n substrate 202. In particular, the vertical walled trench 208 as formed by anisotropic etch and filled with insulating material 212 increases breakdown voltage of the semiconductor device (to 1600 volts or more) by nature of the vertical depletion spread along the vertical insulating trench. The vertical walled trench 208 filled with insulating material 212 extending at least to junction 210 significantly reduces time and cost during manufacturing of the semiconductor wafer, e.g., trench 208 can be formed in about 8 hours or less. Trench 208 can be circular, oval, rounded, curved, polygonal, or other regular or irregular shape, similar to FIGS. 5h-5i. The insulating trench 208, 212 uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

FIG. 11 illustrates a discrete bidirectional trench TVS 220 formed monolithically on semiconductor wafer or substrate 222. Semiconductor wafer 222 contains silicon, germanium, aluminum phosphide, aluminum arsenide, gallium arsenide, gallium nitride, indium phosphide, silicon carbide, or other bulk semiconductor material for structural support. Semiconductor wafer 222 is doped with boron, aluminum, gallium, or indium to have p-type conductivity with a resistivity between 0.5 to 500 ohms-cm.

A plurality of doped semiconductor layers and regions are formed in semiconductor wafer 222 using semiconductor photolithography or implantation manufacturing processes, such as layering, patterning, doping, and heat treatment. An n layer 224 is formed in surface 226 of semiconductor wafer 222 by diffusion or ion implantation of an n-type dopant, such as phosphorus, arsenic, or antimony. In one embodiment, n-type dopant is spun onto surface 226 of semiconductor wafer 222 and then heated in a furnace to 1000-1250° C. for 8 hours or less to drive the n-type dopant to a shallow depth of 40 μm or less (or 20 μm or less) and form n layer 224. A first p-n junction 234 is defined by p substrate 222 and n layer 224. An n layer 228 is formed in surface 230 of semiconductor wafer 222 by diffusion or ion implantation of an n-type dopant, such as phosphorus, arsenic, or antimony. In one embodiment, n-type dopant is spun onto surface 230 of semiconductor wafer 222 and then heated in a furnace to 1000-1250° C. for 8 hours or less to drive the n-type dopant to a shallow depth of 40 μm or less (or 20 μm or less) and form n layer 228. A second p-n junction 240 is defined by p substrate 222 and n layer 228. Substrate 222 and layers 224 and 228 can be formed with respectively opposite conductivity types.

A trench 232 is formed in semiconductor wafer 222 extending through n layer 224, i.e., at least to or past junction 234 defined as the interface between p substrate 222 and n layer 224. In one embodiment, trench 232 is formed using argon as an ionization gas with SF6 etchant or other anisotropic type etchant to create vertical sidewalls. In particular, trench 232 has substantially vertical sidewalls to form a vertical boundary surrounding junction 234. The sidewalls of trench 232 are substantially vertical with respect to surface 226 and substantially square or orthogonal with respect to junction 234 to provide a vertical termination of the junction. Trench 232 extends at least as deep as or deeper than physical junction 234. Trench 232 is filled with an insulating material 236, such as Si3N4, SiON, SiO2, Ta2O5, ZrO2, Al2O3, polysilicon, amorphous silicon, semi-insulating polysilicon, dielectric, or other material having similar properties.

A trench 238 is formed in semiconductor wafer 222 extending through n layer 228, i.e., at least to or past junction 240 defined as the interface between p substrate 222 and n layer 228. In one embodiment, trench 238 is formed using argon as an ionization gas with SF6 etchant or other anisotropic type etchant to create vertical sidewalls. In particular, trench 238 has substantially vertical sidewalls to form a vertical boundary surrounding junction 240. The sidewalls of trench 238 are substantially vertical with respect to surface 230 and substantially square or orthogonal with respect to junction 240 to provide a vertical termination of the junction. Trench 238 extends at least as deep as or deeper than physical junction 240. Trench 238 is filled with an insulating material 242, such as Si3N4, SiON, SiO2, Ta2O5, ZrO2, Al2O3, polysilicon, amorphous silicon, semi-insulating polysilicon, dielectric, or other material having similar properties.

Trenches 232 and 238 can be lined or coated with a thermal oxide layer, such as SiO2, in an oxygen atmosphere at a temperature between 800-1150° C. The lining or coating seals the perimeter of the p-n junction from contamination and provides long-term stability for TVS 220. The insulation-filled trenches are planarized using etch-back or CMP to be even with surfaces 226 and 230 in order to form metallization layers which make low resistance ohmic electrical contact with the opposing regions of TVS 220. An electrically conductive layer is formed over n layers 224 and 228 as contacts to TVS 220, similar to FIG. 5d.

The junction 234 terminated with a vertical walled trench 232 filled with insulating material 236 operates as a vertical boundary and high voltage termination surrounding the junction between p substrate 222 and n layer 224. Likewise, junction 240 terminated with a vertical walled trench 238 filled with insulating material 242 operates as a vertical boundary and high voltage termination surrounding the junction between p substrate 222 and n layer 228. In particular, the vertical walled trenches 232, 238 as formed by anisotropic etch and filled with insulating material 236, 242 increases breakdown voltage of the semiconductor device (to 1600 volts or more) by nature of the vertical depletion spread along the vertical insulating trench. The vertical walled trench 232, 238 filled with insulating material 236, 242, respectively, extending at least to junction 234, 240 significantly reduces time and cost during manufacturing of the semiconductor wafer, e.g., trenches 232 and 238 can be formed in about 8 hours or less. Trenches 232 and 238 can be circular, oval, rounded, curved, polygonal, or other regular or irregular shape, similar to FIGS. 5h-5i. The insulating trench uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

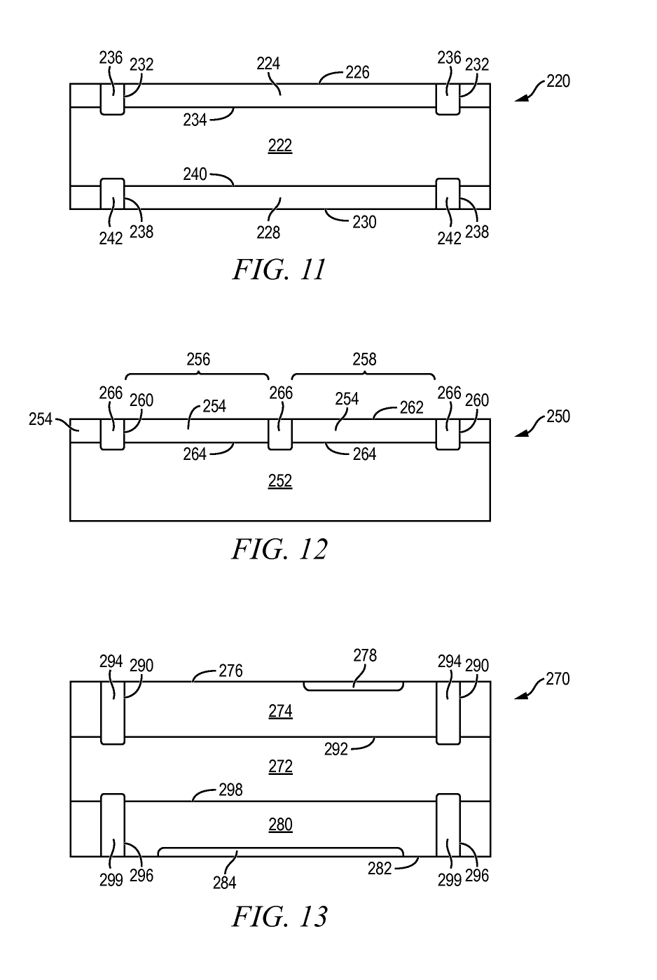

FIG. 12 illustrates a discrete trench TVS 250 formed monolithically on semiconductor wafer or substrate 252. Semiconductor wafer 252 contains silicon, germanium, aluminum phosphide, aluminum arsenide, gallium arsenide, gallium nitride, indium phosphide, silicon carbide, or other bulk semiconductor material for structural support. Semiconductor wafer 252 is doped with phosphorus, arsenic, or antimony to have n-type conductivity with a resistivity between 0.5 to 500 ohms-cm.

A plurality of doped semiconductor layers and regions are formed in semiconductor wafer 252 using semiconductor photolithography or implantation manufacturing processes, such as layering, patterning, doping, and heat treatment. A p layer 254 is formed in surface 262 of semiconductor wafer 252 by diffusion or ion implantation of a p-type dopant, such as boron, aluminum, gallium, or indium. In one embodiment, p-type dopant is spun onto surface 262 of semiconductor wafer 252 and then heated in a furnace to 1000-1250° C. for 8 hours or less to drive the p-type dopant to a shallow depth of 40 μm or less (or 20 μm or less) and form p layer 254. A first p-n junction 264 is defined by p layer 254 and n substrate 252 in area 256. A second p-n junction 264 is defined by p layer 254 and n substrate 252 in area 258. Substrate 252 and layer 254 can be formed with respectively opposite conductivity types.

A trench 260 is formed in semiconductor wafer 252 extending through p layer 254, i.e., at least to or past junction 264 defined as the interface between p layer 254 and n substrate 252. In one embodiment, trench 260 is formed using argon as an ionization gas with SF6 etchant or other anisotropic type etchant to create vertical sidewalls. In particular, trench 260 has substantially vertical sidewalls to form a vertical boundary surrounding junction 264. The sidewalls of trench 260 are substantially vertical with respect to surface 262 and substantially square or orthogonal with respect to junction 264 to provide a vertical termination of the junction. Trench 260 extends at least as deep as or deeper than physical junction 264. Trench 260 is filled with an insulating material 266, such as Si3N4, SiON, SiO2, Ta2O5, ZrO2, Al2O3, polysilicon, amorphous silicon, semi-insulating polysilicon, dielectric, or other material having similar properties.

Trench 260 can be lined or coated with a thermal oxide layer, such as SiO2, in an oxygen atmosphere at a temperature between 800-1150° C. The lining or coating seals the perimeter of the p-n junction from contamination and provides long-term stability for TVS 250. The insulation-filled trench 260, 266 is planarized using etch-back or CMP to be even with surface 262 in order to form metallization layers which make low resistance ohmic electrical contact with regions of TVS 250. An electrically conductive layer is formed over p layer 254 and n substrate 252 as contacts to TVS 250, similar to FIG. 5d.

The junction 264 terminated with a vertical walled trench 260 filled with insulating material 266 operates as a vertical boundary and high voltage termination surrounding the junction between p layer 254 and n substrate 252. In particular, the vertical walled trench 260 as formed by anisotropic etch and filled with insulating material 266 increases breakdown voltage of the semiconductor device (to 1600 volts or more) by nature of the vertical depletion spread along the vertical insulating trench. The vertical walled trench 260 filled with insulating material 266 extending at least to junction 264 significantly reduces time and cost during manufacturing of the semiconductor wafer, e.g., trench 260 can be formed in about 8 hours or less. Trench 260 can be circular, oval, rounded, curved, polygonal, or other regular or irregular shape, similar to FIGS. 5h-5i. The insulating trench 260, 266 uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

FIG. 13 illustrates a discrete trench thyristor or SCR 270 formed monolithically on semiconductor wafer or substrate 272. Semiconductor wafer 272 contains silicon, germanium, aluminum phosphide, aluminum arsenide, gallium arsenide, gallium nitride, indium phosphide, silicon carbide, or other bulk semiconductor material for structural support. Semiconductor wafer 272 is doped with phosphorus, arsenic, or antimony to have n-type conductivity with a resistivity between 0.5 to 500 ohms-cm.

A plurality of doped semiconductor layers and regions are formed in semiconductor wafer 272 using semiconductor photolithography or implantation manufacturing processes, such as layering, patterning, doping, and heat treatment. A p layer 274 is formed in surface 276 of semiconductor wafer 272 by diffusion or ion implantation of a p-type dopant, such as boron, aluminum, gallium, or indium. In one embodiment, p-type dopant is spun onto surface 276 of semiconductor wafer 272 and then heated in a furnace to 1000-1250° C. for 8 hours or less to drive the p-type dopant to a shallow depth of 40 μm or less (or 20 μm or less) and form p layer 274. A first p-n junction 292 is defined by p layer 274 and n substrate 272. An n region 278 is formed in p layer 274 by diffusion or ion implantation of an n− type dopant, such as phosphorus, arsenic, or antimony. A p layer 280 is formed in surface 282 of semiconductor wafer 272 by diffusion or ion implantation of a p-type dopant, such as boron, aluminum, gallium, or indium. In one embodiment, p-type dopant is spun onto surface 282 of semiconductor wafer 272 and then heated in a furnace to 1000-1250° C. for 8 hours or less to drive the p-type dopant to a shallow depth of 40 μm or less (or 20 μm or less) and form p layer 280. A second p-n junction 298 is defined by p layer 280 and n substrate 272. A p+ region 284 is formed in p layer 280 by diffusion or ion implantation of a p− type dopant, such as boron, aluminum, gallium, or indium, for electrical contact. The combination of n region 278, p layer 274, n substrate 272, and p layer 280 form the n-p-n-p regions of SCR 270, which operates as a switch conducting when the gate receives a current pulse and continuing to conduct while forward biased. Substrate 272, layers 274 and 280, and regions 278 and 284 can be formed with respectively opposite conductivity types.

A trench 290 is formed in semiconductor wafer 272 extending through p layer 274, i.e., at least to or past junction 292 defined as the interface between p layer 274 and n substrate 272. In one embodiment, trench 290 is formed using argon as an ionization gas with SF6 etchant or other anisotropic type etchant to create vertical sidewalls. In particular, trench 290 has substantially vertical sidewalls to form a vertical boundary surrounding junction 292. The sidewalls of trench 290 are substantially vertical with respect to surface 276 and substantially square or orthogonal with respect to junction 292 to provide a vertical termination of the junction. Trench 290 extends at least as deep as or deeper than physical junction 292. Trench 290 is filled with an insulating material 294, such as Si3N4, SiON, SiO2, Ta2O5, ZrO2, Al2O3, polysilicon, amorphous silicon, semi-insulating polysilicon, dielectric, or other material having similar properties.

A trench 296 is formed in semiconductor wafer 272 extending through p layer 280, i.e., at least to or past junction 298 defined as the interface between p layer 280 and n substrate 272. In one embodiment, trench 296 is formed using argon as an ionization gas with SF6 etchant or other anisotropic type etchant to create vertical sidewalls. In particular, trench 296 has substantially vertical sidewalls to form a vertical boundary surrounding junction 298. The sidewalls of trench 296 are substantially vertical with respect to surface 282 and substantially square or orthogonal with respect to junction 298 to provide a vertical termination of the junction. Trench 296 extends at least as deep as or deeper than physical junction 298. Trench 296 is filled with an insulating material 299, such as Si3N4, SiON, SiO2, Ta2O5, ZrO2, Al2O3, polysilicon, amorphous silicon, semi-insulating polysilicon, dielectric, or other material having similar properties.

Trenches 290 and 296 can be lined or coated with a thermal oxide layer, such as SiO2, in an oxygen atmosphere at a temperature between 800-1150° C. The lining or coating seals the perimeter of the p-n junction from contamination and provides long-term stability for SCR 270. The insulation-filled trenches are planarized using etch-back or CMP to be even with surfaces 276 and 282 in order to form metallization layers which make low resistance ohmic electrical contact with the opposing regions of SCR 270. An electrically conductive layer is formed over n layer 278 and p+ region 284 as contacts to SCR 270, similar to FIG. 5d.

The junction 292 terminated with a vertical walled trench 290 filled with insulating material 294 operates as a vertical boundary and high voltage termination surrounding the junction between p layer 274 and n substrate 272. Likewise, junction 298 terminated with a vertical walled trench 296 filled with insulating material 299 operates as a vertical boundary and high voltage termination surrounding the junction between p layer 280 and n substrate 272. In particular, the vertical walled trenches 290, 296 as formed by anisotropic etch and filled with insulating material 294, 299, respectively, increases breakdown voltage of the semiconductor device (to 1600 volts or more) by nature of the vertical depletion spread along the vertical insulating trench. The vertical walled trench 290, 296 filled with insulating material 294, 299, respectively, extending at least to junction 292, 298 significantly reduces time and cost during manufacturing of the semiconductor wafer, e.g., trenches 290 and 296 can be formed in about 8 hours or less. Trenches 290 and 296 can be circular, oval, rounded, curved, polygonal, or other regular or irregular shape, similar to FIGS. 5h-5i. The insulating trench uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

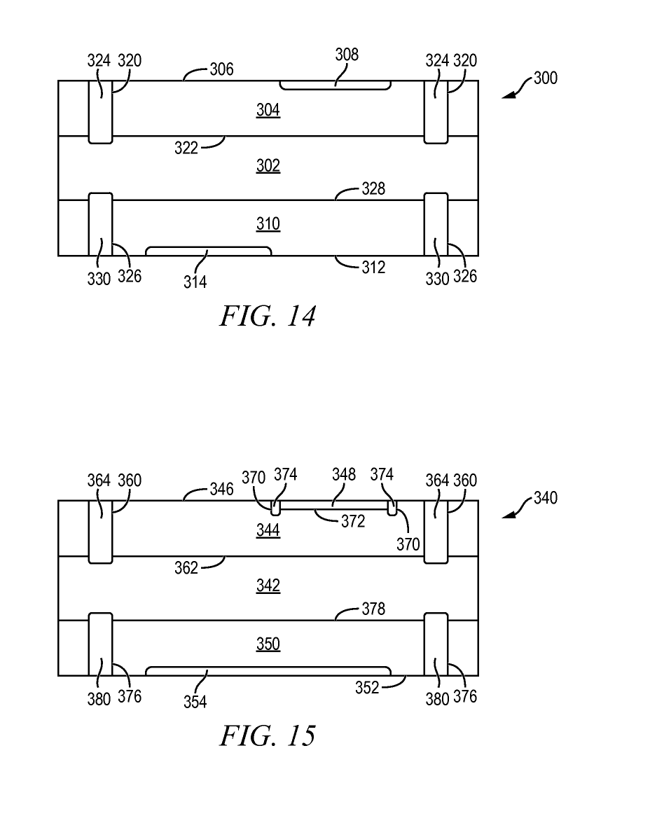

FIG. 14 illustrates a discrete trench triode 300 formed monolithically on semiconductor wafer or substrate 302. Semiconductor wafer 302 contains silicon, germanium, aluminum phosphide, aluminum arsenide, gallium arsenide, gallium nitride, indium phosphide, silicon carbide, or other bulk semiconductor material for structural support. Semiconductor wafer 302 is doped with phosphorus, arsenic, or antimony to have n-type conductivity with a resistivity between 0.5 to 500 ohms-cm.

A plurality of doped semiconductor layers and regions are formed in semiconductor wafer 302 using semiconductor photolithography or implantation manufacturing processes, such as layering, patterning, doping, and heat treatment. A p layer 304 is formed in surface 306 of semiconductor wafer 302 by diffusion or ion implantation of a p-type dopant, such as boron, aluminum, gallium, or indium. In one embodiment, p-type dopant is spun onto surface 306 of semiconductor wafer 302 and then heated in a furnace to 1000-1250° C. for 8 hours or less to drive the p-type dopant to a shallow depth of 40 μm or less (or 20 μm or less) and form p layer 304. A first p-n junction 322 is defined by p layer 304 and n substrate 302. An n region 308 is formed in p layer 304 by diffusion or ion implantation of an n− type dopant, such as phosphorus, arsenic, or antimony. A p layer 310 is formed in surface 312 of semiconductor wafer 302 by diffusion or ion implantation of a p-type dopant, such as boron, aluminum, gallium, or indium. In one embodiment, p-type dopant is spun onto surface 312 of semiconductor wafer 302 and then heated in a furnace to 1000-1250° C. for 8 hours or less to drive the p-type dopant to a shallow depth of 40 μm or less (or 20 μm or less) and form p layer 310. A second p-n junction 328 is defined by p layer 310 and n substrate 302. An n region 314 is formed in p layer 310 by diffusion or ion implantation of an n− type dopant, such as phosphorus, arsenic, or antimony. The combination of n region 308, p layer 304, n substrate 302, p layer 310, and n region 314 provide the bi-directional triode operation. Substrate 302, layers 304 and 310, and regions 308 and 314 can be formed with respectively opposite conductivity types.

A trench 320 is formed in semiconductor wafer 302 extending through p layer 304, i.e., at least to or past junction 322 defined as the interface between p layer 304 and n substrate 302. In one embodiment, trench 320 is formed using argon as an ionization gas with SF6 etchant or other anisotropic type etchant to create vertical sidewalls. In particular, trench 320 has substantially vertical sidewalls to form a vertical boundary surrounding junction 322. The sidewalls of trench 320 are substantially vertical with respect to surface 306 and substantially square or orthogonal with respect to junction 322 to provide a vertical termination of the junction. Trench 320 extends at least as deep as or deeper than physical junction 322. Trench 320 is filled with an insulating material 324, such as Si3N4, SiON, SiO2, Ta2O5, ZrO2, Al2O3, polysilicon, amorphous silicon, semi-insulating polysilicon, dielectric, or other material having similar properties.

A trench 326 is formed in semiconductor wafer 302 extending through p layer 310, i.e., at least to or past junction 328 defined as the interface between p layer 310 and n substrate 302. In one embodiment, trench 326 is formed using argon as an ionization gas with SF6 etchant or other anisotropic type etchant to create vertical sidewalls. In particular, trench 326 has substantially vertical sidewalls to form a vertical boundary surrounding junction 328. The sidewalls of trench 326 are substantially vertical with respect to surface 312 and substantially square or orthogonal with respect to junction 328 to provide a vertical termination of the junction. Trench 326 extends at least as deep as or deeper than physical junction 328. Trench 326 is filled with an insulating material 330, such as Si3N4, SiON, SiO2, Ta2O5, ZrO2, Al2O3, polysilicon, amorphous silicon, semi-insulating polysilicon, dielectric, or other material having similar properties.

Trenches 320 and 326 can be lined or coated with a thermal oxide layer, such as SiO2, in an oxygen atmosphere at a temperature between 800-1150° C. The lining or coating seals the perimeter of the p-n junction from contamination and provides long-term stability for trench triode 300. The insulation-filled trenches are planarized using etch-back or CMP to be even with surfaces 306 and 322 in order to form metallization layers which make low resistance ohmic electrical contact with the opposing regions of trench triode 300. An electrically conductive layer is formed over n region 308 and n region 314 as contacts to trench triode 300, similar to FIG. 5d.

The junction 322 terminated with a vertical walled trench 320 filled with insulating material 324 operates as a vertical boundary and high voltage termination surrounding the junction between p layer 304 and n substrate 302. Likewise, junction 328 terminated with a vertical walled trench 326 filled with insulating material 330 operates as a vertical boundary and high voltage termination surrounding the junction between p layer 310 and n substrate 302. In particular, the vertical walled trenches 320, 326 as formed by anisotropic etch and filled with insulating material 324, 330, respectively, increases breakdown voltage of the semiconductor device (to 1600 volts or more) by nature of the vertical depletion spread along the vertical insulating trench. The vertical walled trench 320, 326 filled with insulating material 324, 330, respectively, extending at least to junction 322, 328 significantly reduces time and cost during manufacturing of the semiconductor wafer, e.g., trenches 320 and 326 can be formed in about 8 hours or less. Trenches 320 and 326 can be circular, oval, rounded, curved, polygonal, or other regular or irregular shape, similar to FIGS. 5h-5i. The insulating trench uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

FIG. 15 illustrates a discrete trench thyristor or SCR 340 formed monolithically on semiconductor wafer or substrate 342. Semiconductor wafer 342 contains silicon, germanium, aluminum phosphide, aluminum arsenide, gallium arsenide, gallium nitride, indium phosphide, silicon carbide, or other bulk semiconductor material for structural support. Semiconductor wafer 342 is doped with phosphorus, arsenic, or antimony to have n-type conductivity with a resistivity between 0.5 to 500 ohms-cm.

A plurality of doped semiconductor layers and regions are formed in semiconductor wafer 342 using semiconductor photolithography or implantation manufacturing processes, such as layering, patterning, doping, and heat treatment. A p layer 344 is formed in surface 346 of semiconductor wafer 342 by diffusion or ion implantation of a p-type dopant, such as boron, aluminum, gallium, or indium. In one embodiment, p-type dopant is spun onto surface 346 of semiconductor wafer 342 and then heated in a furnace to 1000-1250° C. for 8 hours or less to drive the p-type dopant to a shallow depth of 40 μm or less (or 20 μm or less) and form p layer 344. A first p-n junction 362 is defined by p layer 344 and n substrate 342. An n region 348 is formed in p layer 344 by diffusion or ion implantation of an n− type dopant, such as phosphorus, arsenic, or antimony. A p layer 350 is formed in surface 352 of semiconductor wafer 342 by diffusion or ion implantation of a p-type dopant, such as boron, aluminum, gallium, or indium. In one embodiment, p-type dopant is spun onto surface 352 of semiconductor wafer 342 and then heated in a furnace to 1000-1250° C. for 8 hours or less to drive the p-type dopant to a shallow depth of 40 μm or less (or 20 μm or less) and form p layer 350. A second p-n junction 378 is defined by p layer 350 and n substrate 342. A p+ region 354 is formed in p layer 350 by diffusion or ion implantation of a p− type dopant, such as boron, aluminum, gallium, or indium, for electrical contact. The combination of n region 348, p layer 344, n substrate 342, and p layer 350 (n-p-n-p) provide the SCR operation. Substrate 342, layers 344 and 350, and regions 348 and 354 can be formed with respectively opposite conductivity types.

A trench 360 is formed in semiconductor wafer 342 extending through p layer 344, i.e., at least to or past junction 362 defined as the interface between p layer 344 and n substrate 342. In one embodiment, trench 360 is formed using argon as an ionization gas with SF6 etchant or other anisotropic type etchant to create vertical sidewalls. In particular, trench 360 has substantially vertical sidewalls to form a vertical boundary surrounding junction 362. The sidewalls of trench 360 are substantially vertical with respect to surface 346 and substantially square or orthogonal with respect to junction 362 to provide a vertical termination of the junction. Trench 360 extends at least as deep as or deeper than physical junction 362. Trench 360 is filled with an insulating material 364, such as Si3N4, SiON, SiO2, Ta2O5, ZrO2, Al2O3, polysilicon, amorphous silicon, semi-insulating polysilicon, dielectric, or other material having similar properties.

A trench 370 is formed in semiconductor wafer 342 extending partially through p layer 344, i.e., at least to or past junction 372 defined as the interface between p layer 344 and n region 348. In one embodiment, trench 370 is formed using argon as an ionization gas with SF6 etchant or other anisotropic type etchant to create vertical sidewalls. In particular, trench 370 has substantially vertical sidewalls to form a vertical boundary surrounding junction 372. The sidewalls of trench 370 are substantially vertical with respect to surface 346 and substantially square or orthogonal with respect to junction 372 to provide a vertical termination of the junction. Trench 370 extends at least as deep as or deeper than physical junction 372. Trench 370 is filled with an insulating material 374, such as Si3N4, SiON, SiO2, Ta2O5, ZrO2, Al2O3, polysilicon, amorphous silicon, semi-insulating polysilicon, dielectric, or other material having similar properties.

A trench 376 is formed in semiconductor wafer 342 extending through p layer 350, i.e., at least to or past junction 378 defined as the interface between p layer 350 and n substrate 342. In one embodiment, trench 376 is formed using argon as an ionization gas with SF6 etchant or other anisotropic type etchant to create vertical sidewalls. In particular, trench 376 has substantially vertical sidewalls to form a vertical boundary surrounding junction 378. The sidewalls of trench 376 are substantially vertical with respect to surface 352 and substantially square or orthogonal with respect to junction 378 to provide a vertical termination of the junction. Trench 376 extends at least as deep as or deeper than physical junction 378. Trench 376 is filled with an insulating material 380, such as Si3N4, SiON, SiO2, Ta2O5, ZrO2, Al2O3, polysilicon, amorphous silicon, semi-insulating polysilicon, dielectric, or other material having similar properties.

Trenches 360, 370, and 376 can be lined or coated with a thermal oxide layer, such as SiO2, in an oxygen atmosphere at a temperature between 800-1150° C. The lining or coating seals the perimeter of the p-n junction from contamination and provides long-term stability for SCR 340. The insulation-filled trenches are planarized using etch-back or CMP to be even with surfaces 346 and 352 in order to form metallization layers which make low resistance ohmic electrical contact with the opposing regions of SCR 340. An electrically conductive layer is formed over n region 348 and p+ region 354 as contacts to SCR 340, similar to FIG. 5d.

The junction 362 terminated with a vertical walled trench 360 filled with insulating material 364 operates as a vertical boundary and high voltage termination surrounding the junction between p layer 344 and n substrate 342. Likewise, junction 372 terminated with a vertical walled trench 370 filled with insulating material 374 operates as a vertical boundary and high voltage termination surrounding the junction between p layer 350 and n region 348. The junction 378 terminated with a vertical walled trench 376 filled with insulating material 380 operates as a vertical boundary and high voltage termination surrounding the junction between p layer 350 and n substrate 342. In particular, the vertical walled trenches 360, 370, and 376 as formed by anisotropic etch and filled with insulating material 364, 374, 380, respectively, increases breakdown voltage of the semiconductor device (to 1600 volts or more) by nature of the vertical depletion spread along the vertical insulating trench. The vertical walled trench 360, 370, and 376 filled with insulating material 364, 374, 380, respectively, extending at least to junction 362, 372, 378 significantly reduces time and cost during manufacturing of the semiconductor wafer, e.g., trenches 360, 370, and 376 can be formed in about 8 hours or less. Trenches 360, 370, and 376 can be circular, oval, rounded, curved, polygonal, or other regular or irregular shape, similar to FIGS. 5h-5i. The insulating trench uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

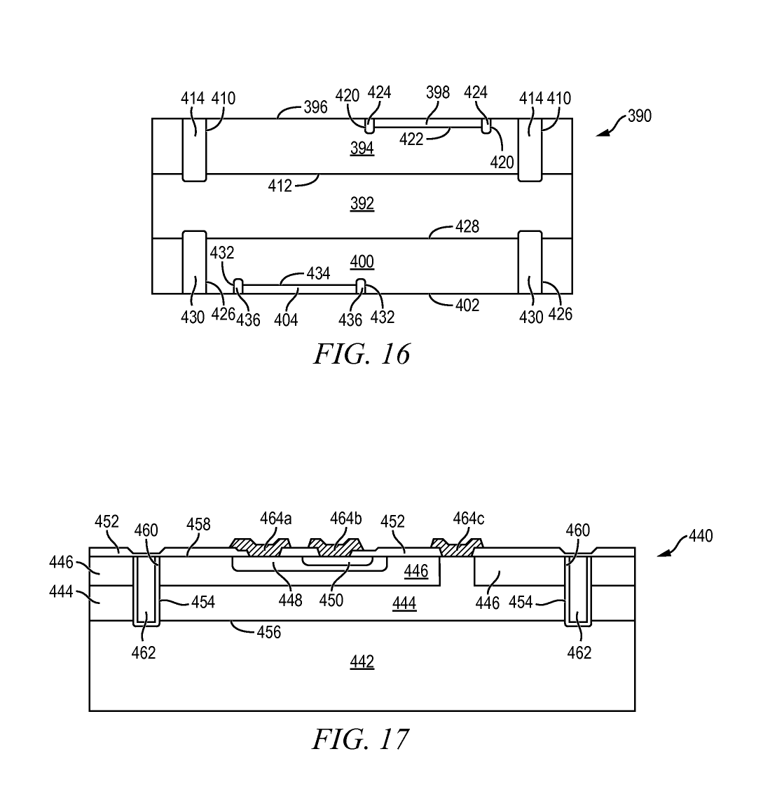

FIG. 16 illustrates a discrete trench triode 390 formed monolithically on semiconductor wafer or substrate 392. Semiconductor wafer 392 contains silicon, germanium, aluminum phosphide, aluminum arsenide, gallium arsenide, gallium nitride, indium phosphide, silicon carbide, or other bulk semiconductor material for structural support. Semiconductor wafer 392 is doped with phosphorus, arsenic, or antimony to have n-type conductivity with a resistivity between 0.5 to 500 ohms-cm.

A plurality of doped semiconductor layers and regions are formed in semiconductor wafer 392 using semiconductor photolithography or implantation manufacturing processes, such as layering, patterning, doping, and heat treatment. A p layer 394 is formed in surface 396 of semiconductor wafer 392 by diffusion or ion implantation of a p-type dopant, such as boron, aluminum, gallium, or indium. In one embodiment, p-type dopant is spun onto surface 396 of semiconductor wafer 392 and then heated in a furnace to 1000-1250° C. for 8 hours or less to drive the p-type dopant to a shallow depth of 40 μm or less (or 20 μm or less) and form p layer 394. A first p-n junction 412 is defined by p layer 394 and n substrate 392. An n region 398 is formed in p layer 394 by diffusion or ion implantation of an n− type dopant, such as phosphorus, arsenic, or antimony. A p layer 400 is formed in surface 402 of semiconductor wafer 392 by diffusion or ion implantation of a p-type dopant, such as boron, aluminum, gallium, or indium. In one embodiment, p-type dopant is spun onto surface 402 of semiconductor wafer 392 and then heated in a furnace to 1000-1250° C. for 8 hours or less to drive the p-type dopant to a shallow depth of 40 μm or less (or 20 μm or less) and form p layer 400. A second p-n junction 428 is defined by p layer 400 and n substrate 392. An n region 404 is formed in p layer 400 by diffusion or ion implantation of an n− type dopant, such as phosphorus, arsenic, or antimony. The combination of n region 398, p layer 394, n substrate 392, p layer 400, and n region 404 provide the bidirectional triac operation. Substrate 392, layers 394 and 400, and regions 398 and 404 can be formed with respectively opposite conductivity types.

A trench 410 is formed in semiconductor wafer 392 extending through p layer 394, i.e., at least to or past junction 412 defined as the interface between p layer 394 and n substrate 392. In one embodiment, trench 410 is formed using argon as an ionization gas with SF6 etchant or other anisotropic type etchant to create vertical sidewalls. In particular, trench 410 has substantially vertical sidewalls to form a vertical boundary surrounding junction 412. The sidewalls of trench 410 are substantially vertical with respect to surface 396 and substantially square or orthogonal with respect to junction 412 to provide a vertical termination of the junction. Trench 410 extends at least as deep as or deeper than physical junction 412. Trench 410 is filled with an insulating material 414, such as Si3N4, SiON, SiO2, Ta2O5, ZrO2, Al2O3, polysilicon, amorphous silicon, semi-insulating polysilicon, dielectric, or other material having similar properties.

A trench 420 is formed in semiconductor wafer 392 extending partially through p layer 394, i.e., at least to or past junction 422 defined as the interface between p layer 394 and n region 398. In one embodiment, trench 420 is formed using argon as an ionization gas with SF6 etchant or other anisotropic type etchant to create vertical sidewalls. In particular, trench 420 has substantially vertical sidewalls to form a vertical boundary surrounding junction 422. The sidewalls of trench 420 are substantially vertical with respect to surface 396 and substantially square or orthogonal with respect to junction 422 to provide a vertical termination of the junction. Trench 420 extends at least as deep as or deeper than physical junction 422. Trench 420 is filled with an insulating material 424, such as Si3N4, SiON, SiO2, Ta2O5, ZrO2, Al2O3, polysilicon, amorphous silicon, semi-insulating polysilicon, dielectric, or other material having similar properties.

A trench 426 is formed in semiconductor wafer 392 extending through p layer 400, i.e., at least to or past junction 428 defined as the interface between p layer 400 and n substrate 392. In one embodiment, trench 426 is formed using argon as an ionization gas with SF6 etchant or other anisotropic type etchant to create vertical sidewalls. In particular, trench 426 has substantially vertical sidewalls to form a vertical boundary surrounding junction 428. The sidewalls of trench 426 are substantially vertical with respect to surface 402 and substantially square or orthogonal with respect to junction 428 to provide a vertical termination of the junction. Trench 426 extends at least as deep as or deeper than physical junction 428. Trench 426 is filled with an insulating material 430, such as Si3N4, SiON, SiO2, Ta2O5, ZrO2, Al2O3, polysilicon, amorphous silicon, semi-insulating polysilicon, dielectric, or other material having similar properties.

A trench 432 is formed in semiconductor wafer 392 extending partially through p layer 400, i.e., at least to or past junction 434 defined as the interface between p layer 400 and n region 404. In one embodiment, trench 432 is formed using argon as an ionization gas with SF6 etchant or other anisotropic type etchant to create vertical sidewalls. In particular, trench 432 has substantially vertical sidewalls to form a vertical boundary surrounding junction 434. The sidewalls of trench 432 are substantially vertical with respect to surface 402 and substantially square or orthogonal with respect to junction 428 to provide a vertical termination of the junction. Trench 432 extends at least as deep as or deeper than physical junction 434. Trench 432 is filled with an insulating material 436, such as Si3N4, SiON, SiO2, Ta2O5, ZrO2, Al2O3, polysilicon, amorphous silicon, semi-insulating polysilicon, dielectric, or other material having similar properties.

Trenches 410, 420, 426, and 432 can be lined or coated with a thermal oxide layer, such as SiO2, in an oxygen atmosphere at a temperature between 800-1150° C. The lining or coating seals the perimeter of the p-n junction from contamination and provides long-term stability for trench triode 390. The insulation-filled trenches are planarized using etch-back or CMP to be even with surfaces 396 and 402 in order to form metallization layers which make low resistance ohmic electrical contact with the opposing regions of trench triode 390. An electrically conductive layer is formed over n region 398 and n region 404 as contacts to trench triode 390, similar to FIG. 5d.

The junction 412 terminated with a vertical walled trench 410 filled with insulating material 414 operates as a vertical boundary and high voltage termination surrounding the junction between p layer 394 and n substrate 392. Likewise, junction 422 terminated with a vertical walled trench 420 filled with insulating material 424 operates as a vertical boundary and high voltage termination surrounding the junction between p layer 394 and n region 398. The junction 428 terminated with a vertical walled trench 426 filled with insulating material 430 operates as a vertical boundary and high voltage termination surrounding the junction between p layer 400 and n substrate 392. The junction 434 terminated with a vertical walled trench 432 filled with insulating material 436 operates as a vertical boundary and high voltage termination surrounding the junction between p layer 400 and n region 404. In particular, the vertical walled trenches 410, 420, 426, 432 as formed by anisotropic etch and filled with insulating material 414, 424, 430, 436, respectively, increases breakdown voltage of the semiconductor device (to 1600 volts or more) by nature of the vertical depletion spread along the vertical insulating trench. The vertical walled trenches 410, 420, 426, 432 filled with insulating material 414, 424, 430, 436, respectively, extending at least to junction 412, 422, 428, 434 significantly reduces time and cost during manufacturing of the semiconductor wafer, e.g., trenches 410, 420, 426, and 432 can be formed in about 8 hours or less. Trenches 410, 420, 426, and 432 can be circular, oval, rounded, curved, polygonal, or other regular or irregular shape, similar to FIGS. 5h-5i. The insulating trench uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

FIG. 17 illustrates a discrete lateral bipolar transistor 440 formed monolithically on semiconductor wafer or substrate 442. Semiconductor wafer 442 contains silicon, germanium, aluminum phosphide, aluminum arsenide, gallium arsenide, gallium nitride, indium phosphide, silicon carbide, or other bulk semiconductor material for structural support. Semiconductor wafer 442 is doped with boron, aluminum, gallium, or indium to have p-type conductivity with a resistivity between 0.5 to 500 ohms-cm.

A plurality of doped semiconductor layers and regions are formed in semiconductor wafer 442 using semiconductor photolithography or implantation manufacturing processes, such as layering, patterning, doping, and heat treatment. More specifically, semiconductor wafer 442 is implanted with n-type dopant, typically phosphorus, arsenic, or antimony, using a sheet-type doping process to form n+ buried layer 444. An n− epi layer 446 is formed in semiconductor wafer 442 over n+ buried layer 444 by sheet-type doping or ion implantation of an n-type dopant such as phosphorus, arsenic, or antimony. The n+ buried layer 444 provides electrical isolation of semiconductor device 130 and reduces pattern washout effects that may occur on Si <111> and Si <100> crystal orientation substrates during formation of n− epi layer 446. The n+ buried layer 444 operates as a collector of transistor 440. A p base well 448 formed in n− epi layer 446. The p base well 448 operates as a base region of transistor 440. An n region 450 is formed in p base well 448. The n region 450 operates as an emitter of transistor 440.

An insulating or passivation layer 452 is formed over n− epi layer 446 using PVD, CVD, printing, lamination, spin coating, spray coating, sintering or thermal oxidation. The insulating layer 452 contains one or more layers of SiO2, Si3N4, SiON, Ta2O5, Al2O3, or other material having similar insulating and structural properties. A plurality of openings is formed through insulating layer 452 by an etching process to expose n− epi layer 446.

Trench 454 is formed in semiconductor wafer 442 aligned with the openings in insulating layer 452 and extending through n− epi layer 446 and n+ buried layer 444 into the substrate, i.e., at least to or past junction 456 defined as the interface between p substrate 442 and n+ buried layer 444. In one embodiment, trench 454 is formed using argon as an ionization gas with SF6 etchant or other anisotropic type etchant to create vertical sidewalls, similar to FIG. 8c. In particular, trench 454 has substantially vertical sidewalls to form a vertical boundary surrounding junction 456 between p substrate 442 and n+ buried layer 444. The sidewalls of trench 454 are substantially vertical with respect to surface 458 and substantially square or orthogonal with respect to junction 456 to provide a vertical termination of the junction. Trench 454 extends at least as deep as or deeper than physical junction 456.

Trench 454 is lined or coated with an insulating layer 460, such as thermal oxide, SiO2, or other material having similar properties, in an oxygen atmosphere at a temperature between 800-1150° C. The insulating layer 460 seals the perimeter of the area above junction 456 from contamination and provides long-term stability for the semiconductor device. Trench 454 is filled with an insulating material 462, such as Si3N4, SiON, SiO2, Ta2O5, ZrO2, Al2O3, polysilicon, amorphous silicon, semi-insulating polysilicon, dielectric, or other material having similar properties. Alternatively, oxynitride is deposited into an unlined trench to protect the area above junction 456 from contamination and increase reliability.

In another embodiment, the insulating-filled trench 454, 460-462 is formed without insulating layer 452. The insulation-filled trench 454, 460-462 is planarized using etch-back or CMP to be even with the surface of n− epi layer 446 in order to form metallization layers which make a low resistance ohmic electrical contact with regions of transistor 440.

The junction 456 terminated with a vertical walled trench 454 filled with insulating material 460-462 operates as a vertical boundary and high voltage termination surrounding the junction between p substrate 442 and n+ buried layer 444. In particular, the vertical walled trench 454 as formed by anisotropic etch and filled with insulating material 460-462 increases breakdown voltage of transistor 440 (to 1600 volts or more) by nature of the vertical depletion spread along the vertical insulating trench. The vertical walled trench 454 filled with insulating material 460-462 extending at least to junction 456 significantly reduces time and cost during manufacturing of semiconductor wafer 442, e.g., trench 454 can be formed in about 8 hours or less. Trench 454 can be circular, oval, rounded, curved, polygonal, or other regular or irregular shape, similar to FIGS. 5h-5i.

The vertical isolating filled trench 454, 460-462 is covered with insulating layer 452. A portion of insulating layer 452 is removed by an etching process to expose portions of n− epi layer 446. An electrically conductive layer 464 is formed over n region 450, p base well 448, and n+ buried layer 444 using PVD, CVD, electrolytic plating, electroless plating process, or other suitable metal deposition process. Conductive layer 464 can be one or more layers of Al, Cu, Sn, Ni, Au, Ag, Ti, or other suitable electrically conductive material. Portions 464a, 464b, and 464c of conductive layer 464 are electrically isolated to form contacts to the base, emitter, and collector of transistor 440, respectively.

Discrete transistor 440 terminates with trench 454 having vertical sidewalls lined with insulating layer 460 and filled with insulating material 462 to define the horizontal boundary as a vertical plane extending at least down to or past the physical junction 456 between p substrate 442 and n+ buried layer 444 to give the semiconductor device significantly improved electrical characteristics. The vertical insulation-filled trench 454, 460-462 increases breakdown voltage and reduces production time for transistor 440. Any electric field imposed by a high voltage terminates at the horizontal boundary established by insulating trench 454, 460-462. In particular, the vertical walled trench 454 as formed by anisotropic etch and filled with insulating material 460-462 increases breakdown voltage of the semiconductor device (to 1600 volts or more) by nature of the vertical depletion spread along the vertical insulating trench. The vertical walled trench 454 filled with insulating material 460-462 extending at least to junction 456 significantly reduces time and cost during manufacturing of the semiconductor wafer, e.g., trench 454 can be formed in about 8 hours or less. Accordingly, insulating trench 454, 460-462 functions as a sealed trench junction termination, which provides a high and uniform breakdown voltage across the device while reducing processing time without increasing the size of the die and complexity of the manufacturing steps. Surface effects on the leakage current around junction 456 are substantially reduced. The sidewall capacitance is reduced which increases the frequency response of transistor 440 for high frequency applications. The insulating trench 454, 460-462 uses a small silicon area for the sealed trench junction termination, while providing improved reliability, die density per wafer, breakdown voltage, high temperature stability, less risk of breakage or contamination, overall manufacturing yield, and mechanical strength for the wafer during subsequent handling in the manufacturing process.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a substrate including a semiconductor material of a first conductivity type;
forming a first layer including a semiconductor material of a second conductivity type in the substrate with a first boundary between the first layer and the semiconductor material of the first conductivity type;
forming a first vertical trench through the first layer extending at least to the first boundary; and
depositing a first insulating material in the first vertical trench.

2. The method of claim 1, further including forming an insulating layer over a sidewall of the first vertical trench.

3. The method of claim 1, further including forming a p-n junction at the first boundary between the first layer and the semiconductor material of the first conductivity type.

4. The method of claim 1, wherein a depth of the first vertical trench is less than 40 micrometers.

5. The method of claim 1, further including:
forming a second layer including the semiconductor material of the second conductivity type in the substrate opposite the first layer with a second boundary between the second layer and the semiconductor material of the first conductivity type;
forming a second vertical trench through the second layer extending at least to the second boundary; and
depositing a second insulating material in the second vertical trench.

6. The method of claim 1, wherein the semiconductor device includes a discrete semiconductor component selected from the group consisting of a diode, transistor, rectifier, transient voltage suppressor, silicon controlled rectifier, and triode.

7. A method of making a semiconductor device, comprising:
providing a substrate including a semiconductor material of a first conductivity type;
forming a first layer including a semiconductor material of a second conductivity type in the substrate;
forming a first vertical trench through the first layer to a depth of less than 40 micrometers; and
depositing a first insulating material in the first vertical trench.

8. The method of claim 7, further including forming an insulating layer over a sidewall of the first vertical trench.

9. The method of claim 7, further including forming a p-n junction a boundary between the first layer and the semiconductor material of the first conductivity type.

10. The method of claim 7, further including:
forming a second layer including the semiconductor material of the second conductivity type in the substrate;
forming a second vertical trench through the second layer; and
depositing a second insulating material in the second vertical trench.

11. The method of claim 7, wherein the first vertical trench includes a rounded or polygonal shape.

12. The method of claim 7, further including forming the first vertical trench by anisotropic etch or laser direct ablation.

13. The method of claim 7, wherein the semiconductor device includes a discrete semiconductor component selected from the group consisting of a diode, transistor, rectifier, transient voltage suppressor, silicon controlled rectifier, and triode.

14. A semiconductor device, comprising:
a substrate including a semiconductor material of a first conductivity type;
a first layer including a semiconductor material of a second conductivity type formed in the substrate with a first boundary between the first layer and the semiconductor material of the first conductivity type;
a first vertical trench formed through the first layer extending at least to the first boundary; and
a first insulating material deposited in the first vertical trench.

15. The semiconductor device of claim 14, further including an insulating layer formed over a sidewall of the first vertical trench.

16. The semiconductor device of claim 14, wherein the first boundary between the first layer and the semiconductor material of the first conductivity type forms a p-n junction.

17. The semiconductor device of claim 14, wherein a depth of the first vertical trench is less than 40 micrometers.

18. The semiconductor device of claim 14, further including:
a second layer including the semiconductor material of the second conductivity type formed in the substrate opposite the first layer with a second boundary between the second layer and the semiconductor material of the first conductivity type;
a second vertical trench formed through the second layer extending at least to the second boundary; and
a second insulating material deposited in the second vertical trench.

19. The semiconductor device of claim 14, wherein the semiconductor device includes a discrete semiconductor component selected from the group consisting of a diode, transistor, rectifier, transient voltage suppressor, silicon controlled rectifier, and triode.

20. A semiconductor device, comprising:
a substrate including a semiconductor material of a first conductivity type;
a first layer including a semiconductor material of a second conductivity type formed in the substrate;
a first vertical trench formed through the first layer to a depth of less than 40 micrometers; and
a first insulating material deposited in the first vertical trench.

21. The semiconductor device of claim 20, further including an insulating layer formed over a sidewall of the first vertical trench.

22. The semiconductor device of claim 20, wherein a boundary between the first layer and the semiconductor material of the first conductivity type forms a p-n junction.

23. The semiconductor device of claim 20, further including:
a second layer including the semiconductor material of the second conductivity type formed in the substrate;
a second vertical trench formed through the second layer; and
a second insulating material deposited in the second vertical trench.

24. The semiconductor device of claim 20, wherein the first vertical trench includes a rounded or polygonal shape.

25. The semiconductor device of claim 20, wherein the semiconductor device includes a discrete semiconductor component selected from the group consisting of a diode, transistor, rectifier, transient voltage suppressor, silicon controlled rectifier, and triode.
